(19) United States
(12) Patent Application Publication
(10) Pub. No.: US 2021/0351445 A1
(43) Pub. Date: Nov. 11, 2021

(54) SEMICONDUCTOR DEVICE

(71) Applicant: DENSO CORPORATION, Kariya-city (JP)

(72) Inventors: KAZUTAKA HONDA, Kariya-city (JP); RYOTARO MIURA, Kariya-city (JP); TAKAHITO HAYAKAWA, Kariya-city (JP)

(21) Appl. No.: 17/383,999

(22) Filed: Jul. 23, 2021

Related U.S. Application Data
(63) Continuation of application No. PCT/JP2020/010286, filed on Mar. 10, 2020.

(30) Foreign Application Priority Data
Mar. 26, 2019 (JP) 2019-058503
Nov. 27, 2019 (JP) 2019-214207

(51) Int. Cl. H01M 10/42

(52) U.S. Cl. CPC H01M 10/4264; H01M 2010/4271; H01M 2220/20; H01M 10/4257

(57) ABSTRACT

A semiconductor device includes: a first semiconductor chip in which a plurality of capacitors are provided by integrating trench capacitors to form a filter that receives, as an input, a physical quantity relating to a plurality of battery cells for forming an assembled battery; a second semiconductor chip in which a circuit is provided, the circuit executing a predetermined process for monitoring the assembled battery based on an output of the filter; and one package that accommodates the first semiconductor chip and the second semiconductor chip.

### CROSS REFERENCE TO RELATED APPLICATION

The present application is a continuation application of International Patent Application No. PCT/JP2020/010286 filed on Mar. 10, 2020, which designated the U.S. and claims the benefit of priority from Japanese Patent Applications No. 2019-058503 filed on Mar. 26, 2019, and No. 2019-214207 filed on Nov. 27, 2019. The entire disclosures of all of the above applications are incorporated herein by reference.

### TECHNICAL FIELD

The present disclosure relates to a semiconductor device for use in monitoring an assembled battery.

### BACKGROUND

Along with an increase in size of a battery pack mounted on a vehicle, a battery monitoring function is disposed in the immediate vicinity of a battery module independently of an electronic control unit (ECU) which is an electronic control device. The size of the battery pack tends to increase in the order of an HEV which is a hybrid vehicle, a PHV which is a plug-in hybrid vehicle, and an EV which is an electric vehicle. The main components of the battery monitoring function include a battery monitoring integrated circuit (IC), a communication unit, and an input filter. A circuit board on which these components are mounted is mounted immediately above a battery module or the like and has thus been strongly required to be reduced in size.

### SUMMARY

According to an example, a semiconductor device includes: a first semiconductor chip in which a plurality of capacitors are provided by integrating trench capacitors to form a filter that receives, as an input, a physical quantity relating to a plurality of battery cells for forming an assembled battery; a second semiconductor chip in which a circuit is provided, the circuit executing a predetermined process for monitoring the assembled battery based on an output of the filter; and one package that accommodates the first semiconductor chip and the second semiconductor chip.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a plan view schematically illustrating a configuration of a semiconductor device according to a first embodiment;

FIG. 2 is a sectional view schematically illustrating the configuration of the semiconductor device according to a first embodiment;

FIG. 3 is a diagram schematically illustrating a circuit configuration related to the semiconductor device according to the first embodiment;

FIG. 4 is a sectional view schematically illustrating a configuration of a filter chip according to the first embodiment;

FIG. 5 is a plane layout view schematically illustrating the configuration of the filter chip according to the first embodiment;

FIG. 6 is a plan view schematically illustrating a configuration of a semiconductor device according to a second embodiment;

FIG. 7 is a plane layout view No. 1 schematically illustrating a configuration of a filter chip according to a third embodiment;

FIG. 8 is a plane layout view No. 2 schematically illustrating the configuration of the filter chip according to the third embodiment;

FIG. 9 is a diagram schematically illustrating a configuration of a semiconductor device according to a fourth embodiment;

FIG. 10 is a diagram schematically illustrating a configuration of a semiconductor device according to a fifth embodiment;

FIG. 11 is a diagram schematically illustrating a configuration of a semiconductor device according to a sixth embodiment;

FIG. 12 is a diagram schematically illustrating a configuration of a semiconductor device according to a seventh embodiment;

FIG. 13 is a diagram schematically illustrating a first configuration of a semiconductor device according to an eighth embodiment;

FIG. 14 is a diagram schematically illustrating a second configuration of the semiconductor device according to the eighth embodiment;

FIG. 15 is a diagram schematically illustrating a third configuration of the semiconductor device according to the eighth embodiment;

FIG. 16 is a diagram schematically illustrating a circuit configuration of a filter in a case where the semiconductor device according to the eighth embodiment has the first configuration;

FIG. 17 is a diagram schematically illustrating a circuit configuration of a filter in a case where the semiconductor device according to the eighth embodiment has the second configuration;

FIG. 18 is a diagram schematically illustrating a circuit configuration of a filter in a case where the semiconductor device according to the eighth embodiment has the third configuration;

FIG. 19 is a perspective view schematically illustrating a configuration of a semiconductor device according to a ninth embodiment;

FIG. 20 is a plan view schematically illustrating the configuration of the semiconductor device according to the ninth embodiment;

FIG. 21 is a diagram schematically illustrating a configuration of a semiconductor device according to a tenth embodiment; and

FIG. 22 is a diagram schematically illustrating a configuration of a semiconductor device and an external component according to a comparative example.

### DETAILED DESCRIPTION

For example, according to a conceivable technique, circuit elements such as a capacitor and a resistor constituting a filter are externally attached to a battery monitoring IC, and these external components contribute to hindrance of a reduction in size of a circuit board.

In view of the above points, a semiconductor device is provided to be capable of reducing the size of a circuit board on which components of a battery monitoring function are to be mounted.

In one aspect of the present embodiments, a semiconductor device includes a first semiconductor chip, a second semiconductor chip, and one package that houses the first semiconductor chip and the second semiconductor chip. In the first semiconductor chip, a plurality of capacitors are each formed by integrating a trench capacitor, the plurality of capacitors constituting filters that receive, as input, physical quantities related to a plurality of battery cells constituting an assembled battery. In the second semiconductor chip, a circuit that executes predetermined processing for monitoring the assembled battery based on the output of the filters is formed.

As thus described, in the above configuration, one package houses the first semiconductor chip in which a plurality of capacitors each constituting the filter, which is one of the components of the battery monitoring function, are formed, and the second semiconductor chip corresponding to a battery monitoring IC, which is one of the components of the battery monitoring function. With such a configuration, it is possible to incorporate, or integrate, the capacitor constituting the filter, which has been conventionally an external component of a battery monitoring IC, into the semiconductor device, and accordingly, it is possible to reduce the size of a circuit board on which the components of the battery monitoring function including the semiconductor device are to be mounted.

In addition, the trench capacitor can achieve a high density of capacitance by forming a trench in a silicon substrate and forming an electrode and a dielectric on the silicon substrate. Therefore, when the trench capacitor is used to form the capacitor constituting the filter as in the above configuration, more capacitors can be incorporated into the semiconductor device, and as a result, the circuit board can be further reduced in size. As thus described, with the above configuration, it is possible to obtain an excellent effect that the circuit board on which the components of the battery monitoring function are to be mounted can be reduced in size.

However, as the withstand voltage of the capacitor constituting the filter described above, it is necessary to consider not only the difference voltage of the battery cell but also the difference in common potential between adjacent filters because the common potential of each filter is different. In the conventional technology related to a trench capacitor, a plurality of elements are not supposed to be integrated, and hence such a point is not taken into consideration, which may cause a problem concerning the withstand voltage of the capacitor.

Therefore, in one aspect of the present embodiments, the first semiconductor chip has a structure for performing element isolation between a region where a predetermined capacitor among the plurality of capacitors is formed and another region. More specifically, the element isolating structure is provided between the region where the predetermined capacitor is formed and a region where another capacitor adjacent to the region is formed.

With such a configuration, the element isolating structure can ensure a difference in common voltage between adjacent capacitors, that is, a common withstand voltage, as a withstand voltage of each capacitor. That is, with the above configuration, as the withstand voltage of each of the plurality of capacitors, it is possible to ensure a withstand voltage in consideration of not only the difference voltage of the battery cell but also the common voltage of each of the adjacent capacitors.

Further, as the withstand voltage of the capacitor constituting the filter described above, it is necessary to also consider the difference in common potential from a region on the back surface side of the first semiconductor chip. Therefore, in one aspect of the present disclosure, the element isolating structure is provided between a region where a predetermined capacitor is formed and a region on the back surface side of the first semiconductor chip. With the above configuration, as the withstand voltage of each of the plurality of capacitors, it is possible to ensure a withstand voltage in consideration of not only the difference voltage of each of the plurality of battery cells but also the difference between the common potential of the region where each capacitor is formed and the potential of the region on the back surface side of the first semiconductor chip.

Hereinafter, a plurality of embodiments will be described with reference to the drawings. In each of the embodiments, substantially the same constituents are denoted by the same reference signs, and the description thereof is omitted.

### First Embodiment

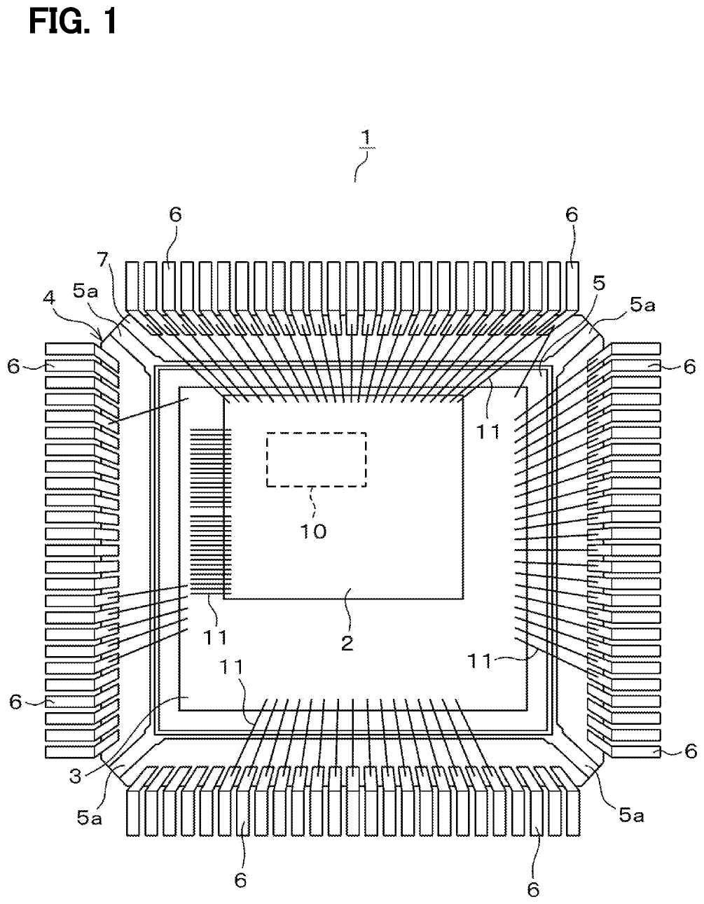

A first embodiment will be described below with reference to FIGS. 1 to 5.

<Overall Configuration>

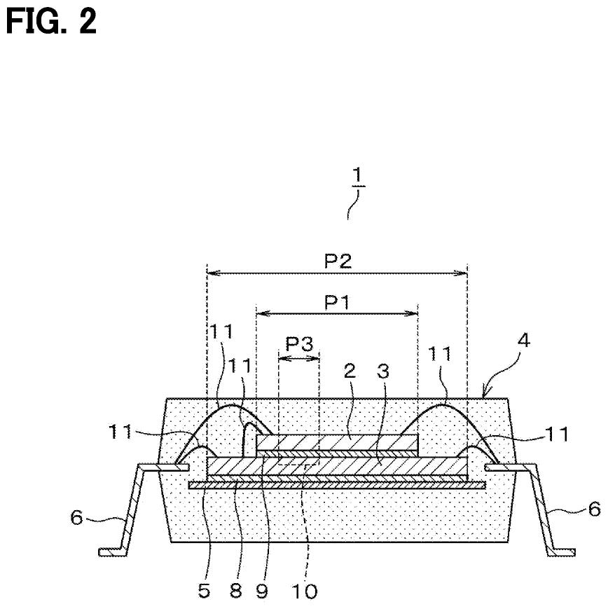

As illustrated in FIGS. 1 and 2, a semiconductor device 1 of the present embodiment is an IC of a multi-chip package in which a plurality of semiconductor chips are housed in one package. In the present specification, the upper side in FIG. 2 is referred to as the front side of the semiconductor device 1, and the lower side in FIG. 2 is referred to as the back side of the semiconductor device 1. In the present specification, the vertical direction in FIG. 1 is referred to as the longitudinal direction of the semiconductor device 1, and the horizontal direction in FIG. 1 is referred to as the lateral direction of the semiconductor device 1.

In this case, the semiconductor device 1 is used in a battery monitoring system for a vehicle, more specifically, a satellite-type battery monitoring system in which a battery monitoring function is disposed in the immediate vicinity of a battery module independently of an ECU. In the satellite-type battery monitoring system, a circuit board on which each component of a battery monitoring function is mounted is attached for each of a plurality of battery modules in order to reduce wiring and the like.

The semiconductor device 1 includes a filter chip 2, a monitoring IC chip 3, and a package 4 for housing the filter chip 2 and the monitoring IC chip 3. The filter chip 2 is a chip in which a plurality of capacitors and a plurality of resistors constituting filters are formed, the filters receiving, as input, physical quantities related to a plurality of battery cells constituting an assembled battery. The filter chip 2 corresponds to a first semiconductor chip. Examples of the physical quantity of the battery cell include voltage and current of the battery cell.

The monitoring IC chip 3 is a chip in which a circuit for executing predetermined processing for monitoring the assembled battery based on the output of the filter is formed and corresponds to a second semiconductor chip. Examples of the predetermined processing include voltage detection for detecting the voltage of the battery cell, communication with an external microcomputer, failure diagnosis as diagnosis such as detection of disconnection or failure of a functional block, and processing such as cell equalization for equalizing the voltage of each battery cell.

The semiconductor device 1 is mounted on a circuit board (not illustrated) together with other components not mounted on the filter chip 2 and the monitoring IC chip 3 among the components of the battery monitoring function. Examples of the other components described above include an element that is a circuit different from the filter and constitutes a circuit related to the input of the physical quantity to the monitoring IC chip 3, a bypass capacitor for reducing fluctuation of the power supply voltage, a damping resistor, a pull-up resistor, and a pull-down resistor. Examples of the elements constituting the circuit related to the input described above include a discharge resistor used for cell equalization and a diode for protecting the circuit from static electricity.

As illustrated in FIGS. 1 and 2, the package 4 includes an island 5, a lead 6, a mold resin 7, and the like. In FIG. 1, only some of the plurality of leads are denoted by reference signs, and reference signs of the other leads are omitted. In this case, the monitoring IC chip 3 and the filter chip 2 are laminated in this order on the surface of the island 5 having a rectangular plate shape and these chips are sealed with the mold resin 7. The island 5 is made of a metal such as copper, iron, or an alloy thereof. As will be described later, the lead 6 is formed of a lead frame material integrated with the island 5. As illustrated in FIG. 1, a suspension lead 5a extends from each of the four corners of the island 5 to the surface of the mold resin 7. The suspension lead 5a inevitably exists when the island 5 is formed of the lead frame material integrated with the lead 6.

The filter chip 2 and the monitoring IC chip 3 are both plate-like semiconductor chips made of a semiconductor such as silicon. The back surface of the monitoring IC chip 3 and the front surface of the island 5 are joined via a joint material 8. In this case, the plane size P1 of the filter chip 2 is smaller than the plane size P2 of the monitoring IC chip 3, and the filter chip 2 is laminated on the monitoring IC chip 3. The back surface of the filter chip 2 and the front surface of the monitoring IC chip 3 are joined via a joint material 9. As the joint material 8, for example, silver paste, solder, or the like is used. As the joint material 9, a die attach film made of a low elasticity resin, that is, a chip bonding film, is used. In the present specification, the die attach film may be abbreviated as DAF.

A reference power supply circuit 10 for generating a reference voltage Vref is formed on the front surface side of the monitoring IC chip 3. The reference voltage Vref is supplied to various circuits formed inside the monitoring IC chip 3. For this reason, when the reference voltage Vref fluctuates, the battery monitoring function may be greatly affected. Therefore, the reference power supply circuit 10 is a circuit having a relatively high degree of importance in terms of a function among the circuits formed in the monitoring IC chip 3 and corresponds to an important circuit.

In this case, a plane size P1 of the filter chip 2 is larger than a plane size P3 of the reference power supply circuit 10. The entire reference power supply circuit 10 is located on the inner periphery of the outer contour of the filter chip 2. That is, the entire reference power supply circuit 10 is covered with the filter chip 2 such that the entire reference power supply circuit 10 is located inside the end of the filter chip 2.

In this case, a plurality of leads 6 are radially provided so as to surround the periphery of the island 5. The lead 6 is formed of a lead frame material in which the island 5 and the lead 6 are integrally connected by a tie bar or the like. After the sealing by the mold resin 7, the lead 6 is cut to be separated from the island 5. The lead 6 may be made of a material different from that of the island 5.

Similarly to the island 5, the lead 6 is made of a metal such as copper or iron. The lead 6 is connected to each of the filter chip 2 and the monitoring IC chip 3 via a wire 11 to be connected electrically. The filter chip 2 and the monitoring IC chip 3 are also connected via the wire 11 to be connected electrically. The wire 11 is formed by usual wire bonding and is made of gold, silver, copper, aluminum, or the like. In FIG. 1, only some of the plurality of wires are denoted by reference signs, and reference signs of the other wires are omitted.

In the above configuration, the island 5, the filter chip 2, the monitoring IC chip 3, the wire 11, and an inner lead, which is a connecting portion with the wire 11 in the lead 6, are sealed with the mold resin 7. An outer lead, which is a portion of the lead 6 opposite to the connecting portion with the wire 11, is exposed from the mold resin 7 and is connected to an external wiring member or the like.

<Circuit Configuration>

As the filter described above, various types of filters such as a low-pass filter, a high-pass filter, and a band-pass filter can be considered, but a low-pass filter is often used in a battery monitoring system. Examples of the low-pass filter used in the battery monitoring system include a single-type or a non-single-type RC filter as disclosed in JP-2017-112677-A cited as a prior art literature. In the present embodiment, the filter described above is a single-type RC filter.

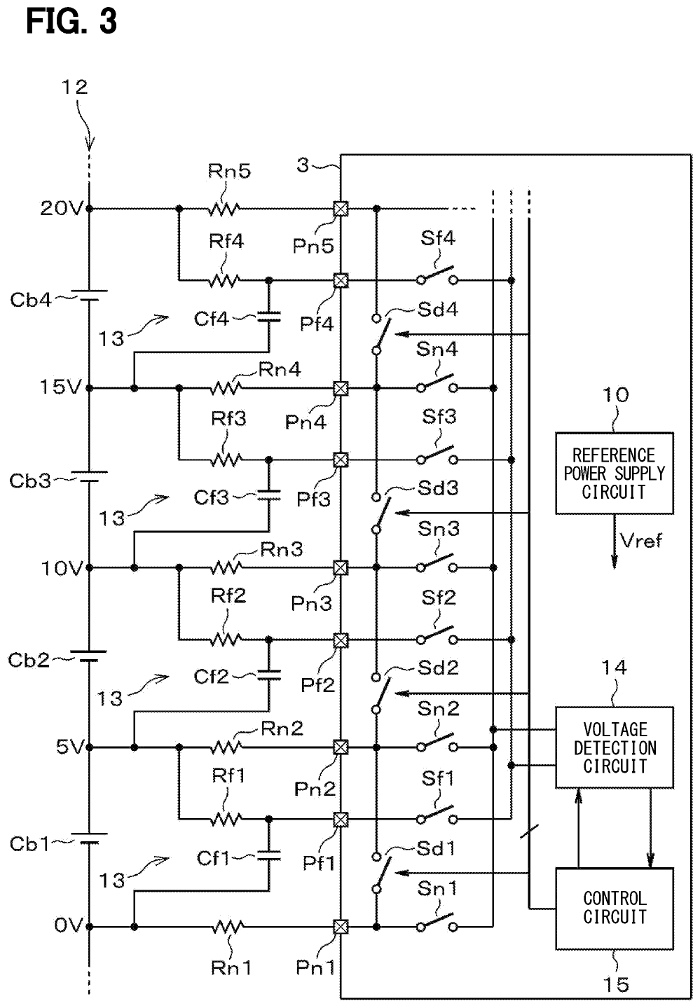

Hereinafter, the circuit configuration of the semiconductor device 1 including the circuit configuration of the filter as thus described will be described with reference to FIG. 3. Although the filter described below has an L-type configuration, the configuration of the filter is not limited thereto, and other configurations such as a n-type may be used. As illustrated in FIG. 3, the assembled battery 12 is mounted on a vehicle, for example, and has a configuration in which a plurality of battery cells Cb are connected in series in multiple stages.

Therefore, a common-mode voltage is superimposed on the battery cell Cb, and the common-mode voltage becomes higher for the battery cell that is connected to the upper stage side of the assembled battery 12, that is, to the high potential side. In the present specification, the common-mode voltage is also referred to as a common voltage. In the present embodiment, the battery cell Cb is formed of, for example, a secondary battery such as a lithium-ion battery, and the cell voltage as the voltage of the battery cell Cb is, for example, 5 V. In the present embodiment, the assembled battery 12 is made up of 24 battery cells Cb. Thus, in the present embodiment, the common voltage of the battery cell Cb is 120 V at the maximum.

In FIG. 3, four battery cells Cb are illustrated, and numbers 1 to 4 are added to the ends of the reference signs in order to distinguish the four battery cells Cb. The respective configurations corresponding to the four battery cells Cb are also distinguished by adding similar numbers to the ends of reference signs. However, in a case where there is no need to distinguish these configurations, the respective configurations will be collectively referred to by omitting the numbers at the ends. Near the high-potential-side terminal and the low-potential-side terminal of the battery cell Cb, examples of respective voltage values are written.

The monitoring IC chip 3 is provided with a connection terminal Pn corresponding to the low-potential-side terminal of each battery cell Cb, and each connection terminal Pn is connected to the low-potential-side terminal of the corresponding battery cell Cb via a discharge resistor Rn. Each of the terminals provided in the monitoring IC chip 3 including the connection terminal Pn corresponds to a pad formed on the semiconductor chip. For example, since a high-potential-side terminal of a battery cell Cb1 is common to a low-potential-side terminal of a battery cell Cb2 on the upper stage side, that is, on the high-voltage side, when a connection terminal corresponding to the high-potential-side terminal of the battery cell Cb is referred to as Pp and the discharge resistor is referred to as Rp, a connection terminal Pp1 corresponds to a connection terminal Pn2 and a discharge resistor Rp1 corresponds to a discharge resistor Rn2.

A series circuit of a resistor Rf and a capacitor Cf is connected between the high-potential-side terminal and the low-potential-side terminal of each battery cell Cb. The resistor Rf and the capacitor Cf constitute a filter 13, which is an RC filter. In the monitoring IC chip 3, filter connection terminals Pf1 to Pf4 are provided between connection terminals Pn corresponding to the respective battery cells Cb. The filter connection terminal Pf is connected to the output terminal of the filter 13 that is a common connection point between the resistor Rf and the capacitor Cf. As thus described, the filter 13 is provided correspondingly to each of the battery cells Cb. Hereinafter, the filter connection terminal Pf will be abbreviated as a connection terminal Pf.

In the above configuration, the resistor Rf and the capacitor Cf constituting the filter 13 are formed in the filter chip 2. In the above configuration, the discharge resistor Rn is provided outside the semiconductor device 1 as an external component. The monitoring IC chip 3 includes a plurality of short-circuiting switches Sd1 to Sd4, a plurality of selection switches Sf1 to Sf4, a plurality of selection switches Sn1 to Sn4, a voltage detection circuit 14, a control circuit 15, the reference power supply circuit 10 for generating the reference voltage Vref described above, and the like. The short-circuiting switches Sd, the selection switches Sf, and the selection switches Sn are each formed of, for example, an N-channel metal-oxide-semiconductor field-effect transistor (MOSFET).

The short-circuiting switches Sd are provided correspondingly to the respective battery cells Cb. The short-circuiting switches Sd are each a switch for short-circuiting between both terminals of the corresponding battery cell Cb. The short-circuiting switches Sd are provided to equalize the variation of the cell voltages of the battery cells Cb by short-circuiting both ends of a battery cell Cb having a higher voltage than those of the other battery cells Cb and discharging the battery cell Cb having a higher voltage.

Inside the monitoring IC chip 3, a short-circuiting switch Sd corresponding to a predetermined battery cell Cb is connected between a connection terminal Pn connected to the high-potential-side terminal of the predetermined battery cell Cb and a connection terminal Pn connected to the low-potential-side terminal thereof. For example, the short-circuiting switch Sd1 corresponding to the battery cell Cb1 is connected between the connection terminals Pn1 and Pn2. The voltage detection circuit 14 detects the voltage of each battery cell Cb via the filter 13.

The control circuit 15 performs on-off control of the short-circuiting switches Sd, the selection switches Sf, and the selection switches Sn and executes various processes described later. In this case, the connection terminals Pn corresponding to the respective battery cells Cb are connected to one input terminal of the voltage detection circuit 14 via the selection switches Sn. The connection terminals Pf corresponding to the respective battery cells Cb are connected to the other input terminal of the voltage detection circuit 14 via the selection switches Sf.

The control circuit 15 performs the on-off control of the selection switches Sf, Sn to perform voltage detection processing for causing the voltage detection circuit 14 to individually detect the voltage of each battery cell Cb. Specifically, at the time of detecting the voltage of a predetermined battery cell Cb, the control circuit 15 performs control so as to turn on the selection switches Sf, Sn corresponding to the predetermined battery cell Cb and to turn off the other selection switches Sf, Sn. Thus, the voltages of both terminals of the predetermined battery cell Cb to be detected are input to the voltage detection circuit 14, and the cell voltage of the predetermined battery cell Cb is detected by the voltage detection circuit 14.

The control circuit 15 performs the on-off control of the short-circuiting switches Sd to execute equalization processing for equalizing the variation of the cell voltages of the battery cells Cb. The equalization processing is performed, for example, as follows. That is, when the variation of the cell voltages of the battery cells Cb acquired from the voltage detection circuit 14 increases, the control circuit 15 determines a battery cell Cb having a high voltage among the battery cells Cb as a discharge target and calculates a discharge time of the battery cell Cb. The control circuit 15 performs the on-off control of a short-circuiting switch Sd corresponding to the battery cell Cb as the discharge target such that the short-circuiting switch Sd is turned on for the calculated discharge time. Hence, the equalization of the battery cells Cb is realized.

In the above configuration, the resistance value of the discharge resistor Rn is smaller than the resistance value of the resistor Rf constituting the filter 13. The resistance values of the respective discharge resistors Rn are designed to be the same value, and the resistance values of the respective resistors Rf constituting the filters 13 are designed to be the same value.

<Configuration of Filter Chip>

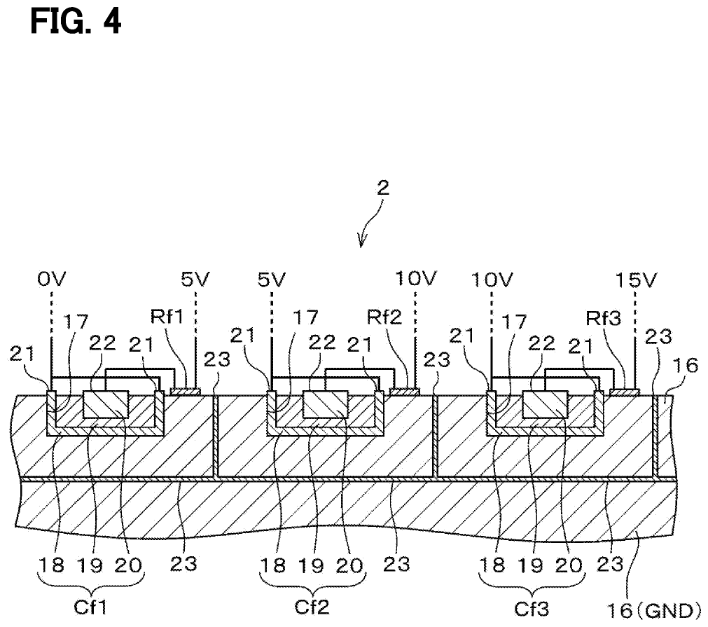

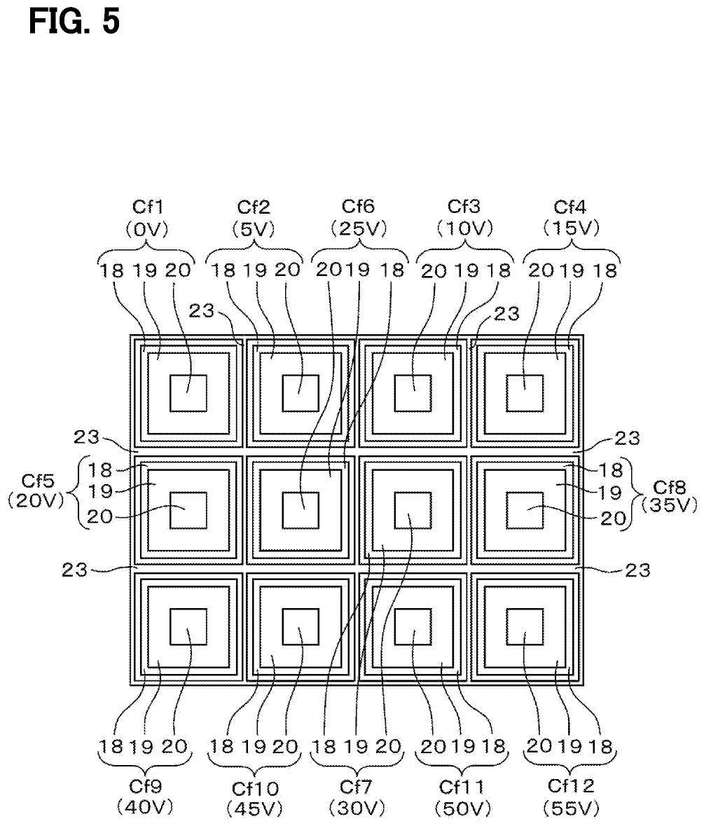

As described above, the resistor Rf and the capacitor Cf constituting the filter 13 are formed in the filter chip 2. In this case, as illustrated in FIG. 4, the resistor Rf is, for example, a polysilicon resistor, that is, a so-called poly resistor, and is formed on a semiconductor substrate 16 such as a silicon substrate. In FIG. 5, the resistor Rf is not illustrated.

As illustrated in FIGS. 4 and 5, the capacitor Cf is formed by integrating a trench capacitor. In general, a trench capacitor is formed by forming a trench in a semiconductor substrate and forming an electrode and a dielectric. Specifically, in this case, the semiconductor substrate 16 is provided with a trench 17 that is a bottomed hole opened on the front surface side and closed on the back surface side.

On the bottom surface and the side surface of the trench 17, that is, on the inner surface of the trench 17, a first conductor 18, a dielectric 19, and a second conductor 20 are laminated in this order from the inner surface side. As the first conductor 18 and the second conductor 20, for example, polysilicon is used. A material having a high dielectric constant is used as the dielectric 19. The first conductor 18 and the second conductor 20 are drawn from the inside of the trench 17 onto the surface of the semiconductor substrate 16, are patterned into desired electrode shapes on the surface, and are constituted as a first electrode 21 and a second electrode 22, respectively.

The resistor Rf and the capacitor Cf as thus configured are wired in a desired connection state in an upper wiring layer (not illustrated) in order to form the filter 13 having the configuration as described above, but in FIG. 4, such wiring is schematically represented by a simple line. In this case, the first electrode 21 is connected to the low-potential-side terminal of the battery cell Cb, and the second electrode 22 is connected to the high-potential-side terminal of the battery cell Cb via the resistor Rf.

For example, in the capacitor Cf1 constituting the filter 13 corresponding to the battery cell Cb1, 0 V being the voltage of the low-potential-side terminal of the battery cell Cb1 is applied to the first electrode 21, and 5 V being the voltage of the high-potential-side terminal of the battery cell Cb1 is applied to the second electrode 22 via the resistor Rf1. The voltage of the semiconductor substrate 16 in the region where the capacitor Cf is formed becomes the voltage of the low-potential-side terminal or the voltage of the high-potential-side terminal of the battery cell Cb. Here, it is assumed that the voltage of the semiconductor substrate 16 uniformly becomes the voltage of the low-potential-side terminal of the battery cell Cb. Therefore, the voltage of the semiconductor substrate 16 in the region where the capacitor Cf1 is formed is 0 V.

In the capacitor Cf2 constituting the filter 13 corresponding to the battery cell Cb2, 5 V being the voltage of the low-potential-side terminal of the battery cell Cb2 is applied to the first electrode 21, and 10 V being the voltage of the high-potential-side terminal of the battery cell Cb2 is applied to the second electrode 22 via the resistor Rf2. Therefore, the voltage of the semiconductor substrate 16 in the region where the capacitor Cf2 is formed is 5 V.

Further, in the capacitor Cf3 constituting the filter 13 corresponding to the battery cell Cb3, 10 V being the voltage of the low-potential-side terminal of the battery cell Cb3 is applied to the first electrode 21, and 15 V being the voltage of the high-potential-side terminal of the battery cell Cb3 is applied to the second electrode 22 via the resistor Rf3. Therefore, the voltage of the semiconductor substrate 16 in the region where the capacitor Cf3 is formed is 10 V.

The voltage of the semiconductor substrate 16 in the region where the capacitor Cf is formed corresponds to the common voltage in each battery cell Cb described above. In FIG. 5, the value of the common voltage is written in parentheses following the reference sign representing each capacitor Cf. These common voltages of the capacitors Cf are different from each other. Hence, the filter chip 2 needs to have a structure in which such a difference in common voltage is taken into consideration between adjacent capacitors Cf.

Therefore, in the present embodiment, between a region where a predetermined capacitor Cf is formed and a region adjacent thereto where another capacitor Cf is formed, a structure for performing element isolation therebetween is formed. In the present embodiment, silicon on insulator, or SOI, is used as a method for element isolation, and the element isolating structure is an isolation layer 23 made of an insulator. Note that the method for element isolation is not limited to the SOI, and various methods that are generally used can be employed, such as junction isolation in which inter-element isolation is formed by the reverse bias of a PN junction.

In this case, the potential on the back surface side of the filter chip 2 is a predetermined fixed potential in the monitoring IC chip 3, specifically, a ground potential in the monitoring IC chip 3. In FIG. 4, “GND” is written in parentheses at a portion of the semiconductor substrate 16 which has the ground potential. Therefore, in the present embodiment, also between each region where the capacitor Cf is provided and a region on the back surface side of the filter chip 2, the isolation layer 23 to be a structure for performing element isolation therebetween is provided. As thus described, in the above configuration, the isolation layer 23 is provided so as to partition the two adjacent regions of the capacitors Cf and to partition the region of the capacitor Cf and the region on the back surface side of the filter chip 2. In other words, the filter chip 2 is provided with a structure for performing element isolation between a region where a predetermined capacitor Cf among the plurality of capacitors Cf is formed and another region.

As illustrated in FIG. 5, a plurality of capacitors Cf are arranged in a matrix in a plane direction of the filter chip 2 so as to be arranged in the lateral direction and arranged in the longitudinal direction. Note that the lateral direction corresponds to a first direction, and the longitudinal direction corresponds to a second direction orthogonal to the first direction. Although only the arrangement of the 12 capacitors Cf1 to Cf12 are illustrated in FIG. 5, other capacitors Cf are also arranged similarly to the capacitors Cf1 to Cf12.

In this case, the arrangement order of the capacitors Cf in the lateral direction is set such that the difference between the common voltages of the two capacitors Cf adjacent to each other in the lateral direction becomes a voltage corresponding to the cell voltage of 5 V. That is, in this case, the four capacitors Cf are arranged in the order from the left such that the common voltage increases by 5 V. For example, focusing on the top row, from the left, the capacitor Cf1 having a common voltage of 0 V, the capacitor Cf2 having a common voltage of 5 V, the capacitor Cf3 having a common voltage of 10 V, and the capacitor Cf4 having a common voltage of 15 V are arranged in this order.

In this case, the arrangement order of the capacitors Cf in the longitudinal direction is set such that the difference between the common voltages of the two capacitors Cf adjacent to each other in the longitudinal direction becomes a voltage obtained by multiplying the cell voltage of 5 V by “4” which is the number of the capacitors Cf arranged in the lateral direction, that is, “5 V×4=20 V”. That is, in this case, the three capacitors Cf are arranged in the order from top to bottom such that the common voltage increases by 20 V. For example, focusing on the leftmost column, the capacitor Cf1 having a common voltage of 0 V, the capacitor Cf5 having a common voltage of 20 V, and the capacitor Cf9 having a common voltage of 40 V are arranged in this order from the top.

With the above configuration, the withstand voltage between the two capacitors Cf adjacent to each other in the lateral direction only needs to be equal to or higher than a voltage corresponding to 5 V, and the withstand voltage between the two capacitors Cf adjacent in the longitudinal direction only needs to be equal to or higher than a voltage corresponding to 20 V. Therefore, the thickness of the isolation layer 23 is relatively small in a portion partitioning between the capacitors Cf adjacent to each other in the lateral direction, and the thickness is relatively large in a portion partitioning between the capacitors Cf adjacent to each other in the longitudinal direction.

The thickness of a portion of the isolation layer 23, the portion partitioning the region of each capacitor Cf and the region on the back surface side of the filter chip 2, is the same throughout the entire region. The thickness in this case only needs to be such that a withstand voltage corresponding to a potential difference (e.g., 120 V) between the region where the capacitor Cf corresponding to the battery cell Cb having the highest common voltage is formed and the region on the back surface side can be ensured.

According to the present embodiment described above, the following effects can be obtained.

The semiconductor device 1 is an IC of a multi-chip package in which one package 4 houses the filter chip 2 in which a plurality of capacitors Cf each constituting the filter 13 are formed and the monitoring IC chip 3 in which a circuit for executing various processing based on the output of the filter 13 is formed. With such a configuration, it is possible to incorporate, or integrate, the capacitor Cf constituting the filter 13, which has been conventionally an external component of an IC, into the semiconductor device 1, and accordingly, it is possible to reduce the size of a circuit board on which the components of the battery monitoring function including the semiconductor device 1 are to be mounted.

The capacitor Cf is formed in the filter chip 2 by integrating a trench capacitor. The trench capacitor can achieve a high density of capacitance by forming a trench in a silicon substrate and forming an electrode and a dielectric on the silicon substrate. Therefore, when the trench capacitor is used to form the capacitor Cf constituting the filter 13 as in the above configuration, more capacitors Cf can be incorporated into the semiconductor device 1, and as a result, the circuit board can be further reduced in size. As thus described, according to the present embodiment, it is possible to obtain an excellent effect that the circuit board on which the components of the battery monitoring function are to be mounted can be reduced in size.

However, as the withstand voltage of the capacitor Cf constituting the filter 13, it is necessary to consider not only the difference voltage of the battery cells Cb but also the difference in common voltage between adjacent filters because the common voltage of each filter 13 is different. In the conventional technology related to a trench capacitor, a plurality of elements are not supposed to be integrated, and hence such a point is not taken into consideration, which may cause a problem concerning the withstand voltage of the capacitor Cf.

Therefore, the filter chip 2 of the present embodiment is provided with a structure for performing element isolation between a region where a predetermined capacitor Cf among the plurality of capacitors Cf is formed and another region. More specifically, the isolation layer 23, which is the element isolating structure, is provided between a region where the predetermined capacitor Cf is formed and a region adjacent thereto where another capacitor Cf is formed. With such a configuration, the isolation layer 23 can ensure a difference in common voltage between adjacent capacitors Cf, that is, a common withstand voltage, as a withstand voltage of each capacitor. That is, with the above configuration, as the withstand voltage of each of the plurality of capacitors Cf, it is possible to ensure a withstand voltage in consideration of not only the difference voltage of the battery cell Cb but also the common voltage of each of the adjacent capacitors.

Further, as the withstand voltage of the capacitor Cf constituting the filter 13, it is necessary to also consider the difference in common voltage from a region on the back surface side of the filter chip 2. Therefore, in the filter chip 2 of the present embodiment, the isolation layer 23 is also provided between the region where the predetermined capacitor Cf is formed and the region on the back surface side of the filter chip 2. With such a configuration, as the withstand voltage of each capacitor Cf, it is possible to ensure a withstand voltage in consideration of not only the difference voltage of the battery cells Cb but also the difference between the common voltage of the region where each of the plurality of capacitors Cf is formed and the voltage of the region on the back surface side of the filter chip 2.

In the above configuration, the potential on the back surface side of the filter chip 2 is the ground potential of the monitoring IC chip 3. With such a configuration, the problem of the back surface potential of the filter chip 2 and the potentials of the monitoring IC chip 3 and the island 5 is less likely to occur, so that as the joint material 9, which is the DAF, a material having a relatively low insulating performance can be used. That is, with the above configuration, the requirements required for the joint material 9 can be relaxed.

In the filter chip 2, the resistor Rf constituting the filter 13 is also formed. In this way, it is possible to incorporate, or integrate, the resistor Rf constituting the filter 13, which has been conventionally an external component of an IC, into the semiconductor device 1, and accordingly, it is possible to further reduce the size of a circuit board on which the components of the battery monitoring function including the semiconductor device 1 are to be mounted.

The discharge resistor Rn can also be formed in the filter chip 2, that is, be integrated. However, since the resistor Rn generates heat during the execution of the equalization processing, when the resistor Rn is integrated, the semiconductor device 1 generates heat more, which may cause a problem. Therefore, in the present embodiment, the discharge resistor Rn is provided as an external component outside the semiconductor device 1. In this way, the heat generation of the semiconductor device 1 can be reduced compared to a case where the resistor Rn is integrated.

In the above configuration, the filter chip 2 is laminated on the monitoring IC chip 3. The plane size of the filter chip 2 is larger than the plane size of the reference power supply circuit 10 formed in the monitoring IC chip 3, and the entire reference power supply circuit 10 is covered with the filter chip 2 such that the entire reference power supply circuit 10 is located on the inner periphery of the outer contour of the filter chip 2. With such a configuration, the following effects can be obtained.

That is, it is known that in a semiconductor device, a voltage value of a reference power supply fluctuates due to the influence of stress caused by the expansion and contraction of a package. With the above configuration, since the filter chip 2 is mounted so as to cover the entire reference power supply circuit 10 of the monitoring IC chip 3, the influence of stress is reduced, and as a result, the fluctuation of the reference voltage Vref generated by the reference power supply circuit 10 can be reduced. Such a function of relaxing the influence of stress is disclosed in JP-2015-153985-A, and hence a detailed description thereof will be omitted here.

The plurality of capacitors Cf are arranged in a matrix in the plane direction of the filter chip 2 so as to be arranged in the lateral direction and arranged in the longitudinal direction. The arrangement order of the capacitors Cf in the lateral direction is set such that the difference between the common voltages of the two capacitors Cf adjacent to each other in the lateral direction becomes a voltage corresponding to the cell voltage. With the above configuration, the withstand voltage between the two capacitors Cf adjacent to each other in the lateral direction only needs to be equal to or greater than a voltage corresponding to 5 V, which is the lowest, as the difference in common voltage, and the thickness of the isolation layer 23 partitioning between the two capacitors Cf adjacent to each other in the lateral direction can be reduced.

In the above configuration, the arrangement order of the capacitors Cf in the longitudinal direction is set such that the difference between the common voltages of the two capacitors Cf adjacent to each other in the longitudinal direction becomes a voltage obtained by multiplying the cell voltage by the number of the capacitors arranged in the lateral direction. With the above configuration, since the withstand voltage between the two capacitors Cf adjacent to each other in the longitudinal direction only needs to be equal to or higher than the same voltage (c.f., 20 V), the thickness of the isolation layer 23 partitioning the two capacitors Cf in the lateral direction can be made uniform to be a minimum necessary thickness

### Second Embodiment

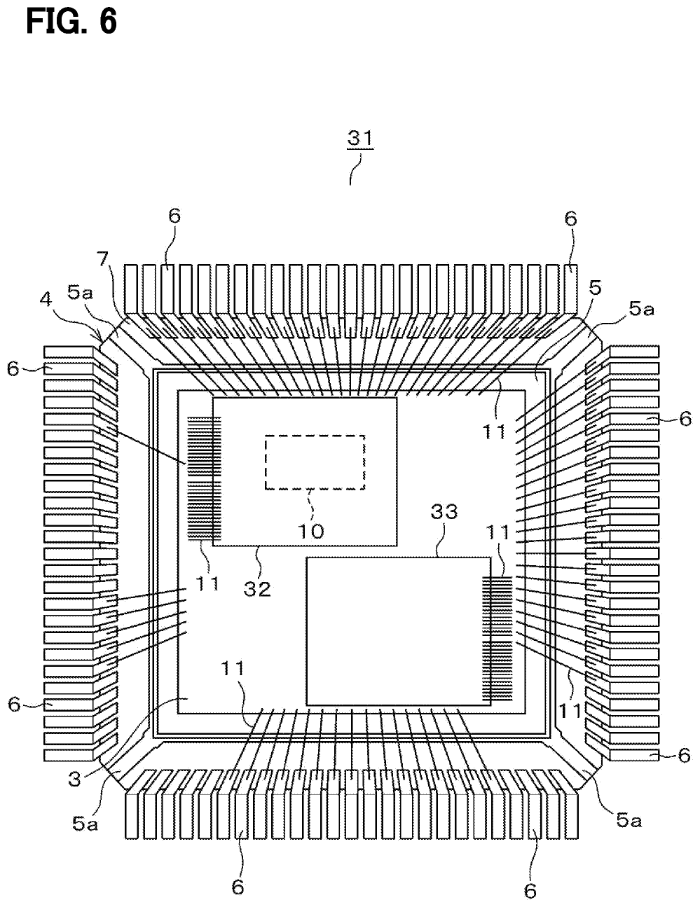

A second embodiment will be described below with reference to FIG. 6.

The filter chip 2, which is the first semiconductor chip in which a plurality of capacitors Cf each constituting the filter 13 are formed, may be divided into a plurality of parts. In other words, the semiconductor device may include a plurality of first semiconductor chips. Therefore, in the present embodiment, a configuration example of the semiconductor device including a plurality of first semiconductor chips will be described.

As illustrated in FIG. 6, a semiconductor device 31 of the present embodiment includes two filter chips 32, 33, a monitoring IC chip 3, and a package 4 for housing the filter chips 32, 33 and the monitoring IC chip 3. The filter chip 32 includes some capacitors Cf among the plurality of capacitors Cf. The filter chip 33 includes capacitors Cf different from those included in the filter chip 32 among the plurality of capacitors Cf.

In the present embodiment, the filter chips 32, 33 are laminated on the monitoring IC chip 3. Although not illustrated, the back surfaces of the filter chips 32, 33 and the front surface of the monitoring IC chip 3 are joined via a joint material 9. The filter chips 32, 33 are disposed side by side on the front surface of the monitoring IC chip 3, that is, arranged side by side in a planar shape. In this case, the entire reference power supply circuit 10 is covered with the filter chip 32.

The present embodiment described above also provides the same effects as those of the first embodiment. Further, with the configuration of the present embodiment including the two filter chips 32, 33, the withstand voltage requirement is dispersed compared to the configuration of the first embodiment including one filter chip 2. That is, in this case, in one filter chip 32 or 33, the voltage difference between the region having the lowest common voltage and the region having the highest common voltage among the regions where the capacitors Cf are formed is lower than that in the first embodiment, and more specifically, as low as about half of that in the first embodiment. Therefore, according to the present embodiment, it is possible to reduce the thickness of the isolation layer 23.

### Third Embodiment

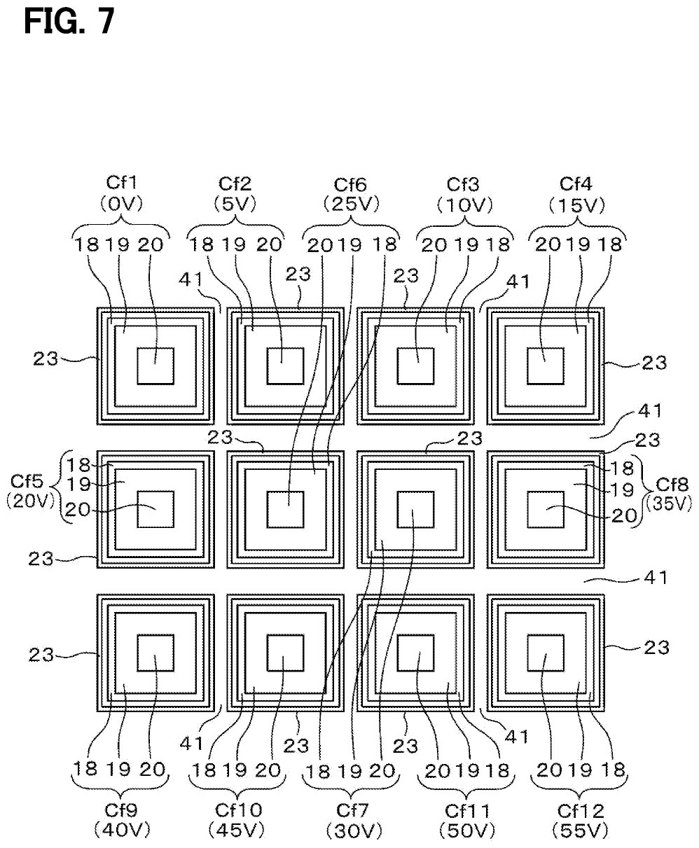

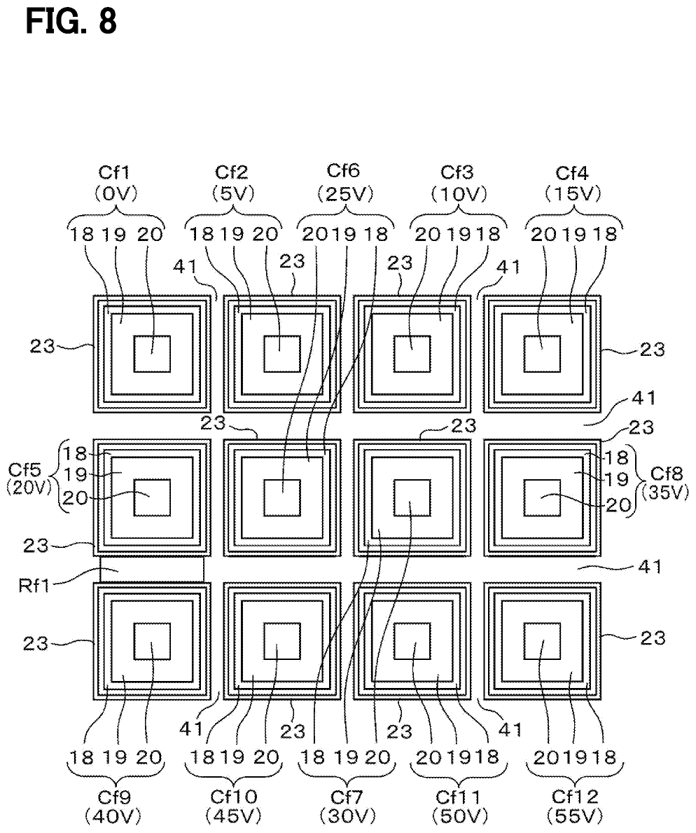

A third embodiment will be described below with reference to FIGS. 7 and 8.

As illustrated in FIG. 7, in the present embodiment, the arrangement of the plurality of capacitors Cf in the plane direction of the filter chip 2, that is, a plane layout, is changed with respect to the first embodiment. In this case, adjacent capacitors Cf are not close to each other, and there is a slight gap therebetween. A field GND, which is a region 41 having a ground potential (0 V), is formed in the gap.

That is, in the present embodiment, the region 41 having a predetermined fixed potential is formed between adjacent capacitors Cf. In this case, each of the capacitors Cf is adjacent to the region 41 having the ground potential. Therefore, in the present embodiment, the thickness of the isolation layer 23 provided so as to partition the adjacent areas, that is, to partition the regions of the adjacent capacitors Cf, needs to be made larger than in the first embodiment.

According to the present embodiment described above, the predetermined capacitor Cf and another capacitor Cf adjacent thereto can be reliably isolated by the region 41 having the ground potential. Thus, for example, when noise is superimposed on a predetermined capacitor Cf2 (5 V), the noise is prevented from being mixed into other adjacent capacitors Cf1 (0 V) and Cf3 (10 V) via the isolation layer 23.

With the above configuration, when the resistor Rf is a poly resistor, as illustrated in FIG. 8, the resistor Rf can be formed on the semiconductor substrate 16 in the region 41. In this way, the region for forming the capacitor Cf can be made smaller by the amount of the resistor Rf formed in the region 41, and as a result, the reduction in area efficiency due to the addition of the region 41 can be compensated.

### Fourth Embodiment

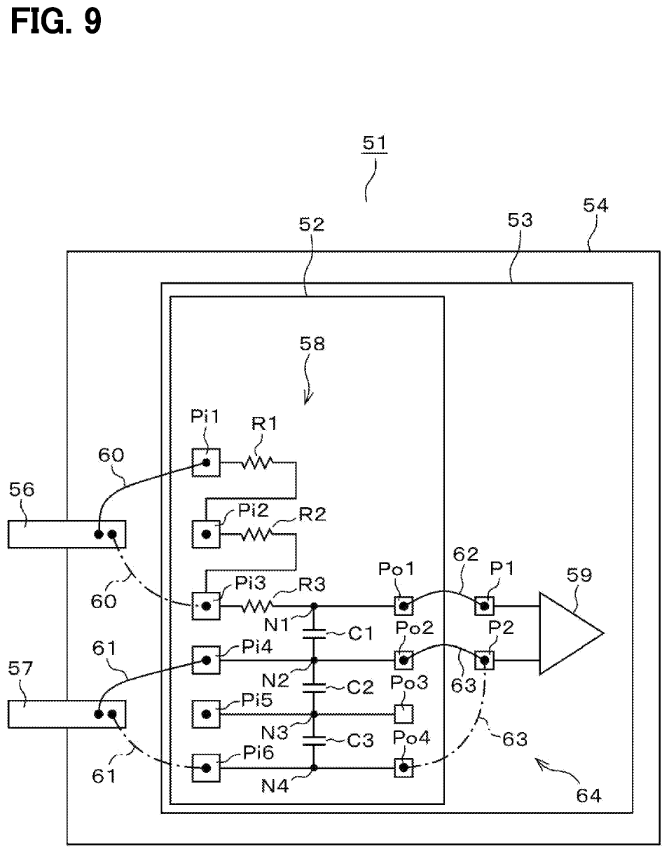

A fourth embodiment will be described below with reference to FIG. 9.

According to each of the embodiments described above, although it is possible to obtain an excellent effect that the circuit board on which the components of the battery monitoring function are to be mounted can be reduced in size, other problems may occur as follows. In other words, the optimum constant and the optimum configuration of the filter vary depending on the noise environment, the usage state, and the like. The noise environment, the usage state, and the like may be different for each system of the vehicle to which the battery monitoring system is applied.

When circuit elements such as a capacitor Cf and a resistor Rf constituting the filter are externally attached to an IC that is a semiconductor device, it is easy to change the constants and configurations of the circuit elements, and an optimum filter can be realized for each system. However, when the circuit elements of the filters are incorporated into the IC package 4 as in each of the above embodiments, it becomes difficult to change the constants of the circuit elements, and it becomes difficult to realize the optimum filter for each system.

In the present embodiment, in order to solve such a problem, the following structure is adopted. That is, as illustrated in FIG. 9, a semiconductor device 51 of the present embodiment includes a filter chip 52 corresponding to the first semiconductor chip, a monitoring IC chip 53 corresponding to the second semiconductor chip, and a package 54 housing the filter chip 52 and the monitoring IC chip 53. Although FIG. 9 illustrates only a configuration for detecting the voltage of one battery cell Cb, the configurations for detecting the voltages of the other battery cells Cb are the same.

The voltage of the high-potential-side terminal of the battery cell Cb is applied to a lead 56 of a package 54. The voltage of the low-potential-side terminal of the battery cell Cb is applied to a lead 57 of the package 54. In the filter chip 52, circuit elements constituting a filter 58 having the same role as the filter 13 in each of the above embodiments are formed. In this case, the filter 58 is a single-type RC filter.

The filter 58 includes resistors R1 to R3 and capacitors C1 to C3. The resistors R1 to R3 and the capacitors C1 to C3 may have the same configurations as those of the resistors Rf and the capacitors Cf in each of the above embodiments. The resistor R1 is connected between a pad Pi1 and a pad Pi2. The resistor R2 is connected between the pad Pi2 and a pad Pi3. The resistor R3 is connected between the pad Pi3 and a node N1ds.

The capacitor C1 is connected between the node N1 and a node N2. The capacitor C2 is connected between the node N2 and a node N3. The capacitor C3 is connected between the node N3 and a node N4. The node N1 is connected to a pad Po1. The node N2 is connected to a pad Pi4 and a pad Po2. The node N3 is connected to a pad Pi5 and a pad Po3. The node N4 is connected to a pad Pi6 and a pad Po4.

A battery monitoring unit 59 is formed in the monitoring IC chip 53. The battery monitoring unit 59 is configured to detect the voltage of the battery cell Cb and has the same functions as those of the voltage detection circuit 14, the control circuit 15, and the like in each of the above embodiments. The battery monitoring unit 59 has one input terminal connected to a pad P1 and the other input terminal connected to a pad P2.

The lead 56 is selectively connected to any one of the pads Pi1 to Pi3 of the filter chip 52 via a wire 60. For example, when the semiconductor device 51 is for a predetermined system A, the lead 56 is connected to the pad Pi1 via the wire 60 as indicated by a solid line in FIG. 9. When the semiconductor device 51 is for another system B different from the system A, the lead 56 is connected to the pad Pi3 via the wire 60 as indicated by a dashed-dotted line in FIG. 9.

The lead 57 is selectively connected to any one of the pads Pi4 to Pi6 of the filter chip 52 via a wire 61. For example, when the semiconductor device 51 is for the system A, the lead 57 is connected to the pad Pi4 via the wire 61 as indicated by a solid line in FIG. 9. When the semiconductor device 51 is for the system B, the lead 57 is connected to the pad Pi6 via the wire 61 as indicated by a dashed-dotted line in FIG. 9.

The pad P1 of the monitoring IC chip 53 is connected to the pad Pot of the filter chip 52 via a wire 62. The pad P2 of the monitoring IC chip 53 is selectively connected to any one of the pads Pot to Po4 of the filter chip 52 via a wire 63. For example, when the semiconductor device 51 is for the system A, the pad P2 is connected to the pad Pot via the wire 63 as indicated by a solid line in FIG. 9. When the semiconductor device 51 is for the system B, the pad P2 is connected to the pad Po4 via the wire 63 as indicated by a dashed-dotted line in FIG. 9.

The wires 60 to 63 are bonding wires, and the same structure as that of the wire 11 or the like in each of the above embodiments can be adopted. In this case, the wires 60, 61, 63 function as a function switching unit 64 that selectively switches the function of the filter 58, specifically, a constant of the filter 58. The constant of the filter 58 is the value of the circuit element for contributing to the cutoff frequency of the filter 58 and corresponds to the resistance value and the capacitance value of the filter 58 that is an RC filter. The function switching unit 64 switches the connection mode of the wires 60, 61, 63 connected to the filter chip 52 to switch the function of the filter 58.

With the above configuration, when the semiconductor device 51 is for the system A, the connection mode of the wires 60, 61, 63 is switched as illustrated by the solid lines in FIG. 9, so that the resistance value of the filter 58 becomes the series combined resistance value of the resistors R1, R2, R3, and the capacitance value of the filter 58 becomes the capacitance value of the capacitor C1. With the above configuration, when the semiconductor device 51 is for the system B, the connection mode of the wires 60, 61, 63 is switched as illustrated by the dashed-dotted lines in FIG. 9, so that the resistance value of the filter 58 becomes the resistance value of the resistor R3, and the capacitance value of the filter 58 becomes the series combined capacitance value of the capacitors C1, C2, C3.

With the configuration of the present embodiment described above, the function of the filter 58, specifically, the constant of the filter 58, can be switched selectively. Therefore, according to the present embodiment, the constant of the filter 58 can be optimized in accordance with the system of the vehicle to which the battery monitoring system is applied, that is, the optimum filter 58 can be realized. In addition, with the configuration of the present embodiment, since the constant, and hence the cutoff frequency, of the filter 58 can be easily changed, it is possible to cope with a system in a wide noise environment.

Furthermore, with the configuration of the present embodiment, the constant of the filter 58 can be switched by switching the connection mode of the bonding wire without changing the configuration of the filter chip 52 and the monitoring IC chip 53. Therefore, according to the present embodiment, the semiconductor device 51 for a plurality of systems can be manufactured using one type of filter chip 52 and one type of monitoring IC chip 53, and the manufacturing cost can be reduced because the chips 52 and 53 can be shared.

### Fifth Embodiment

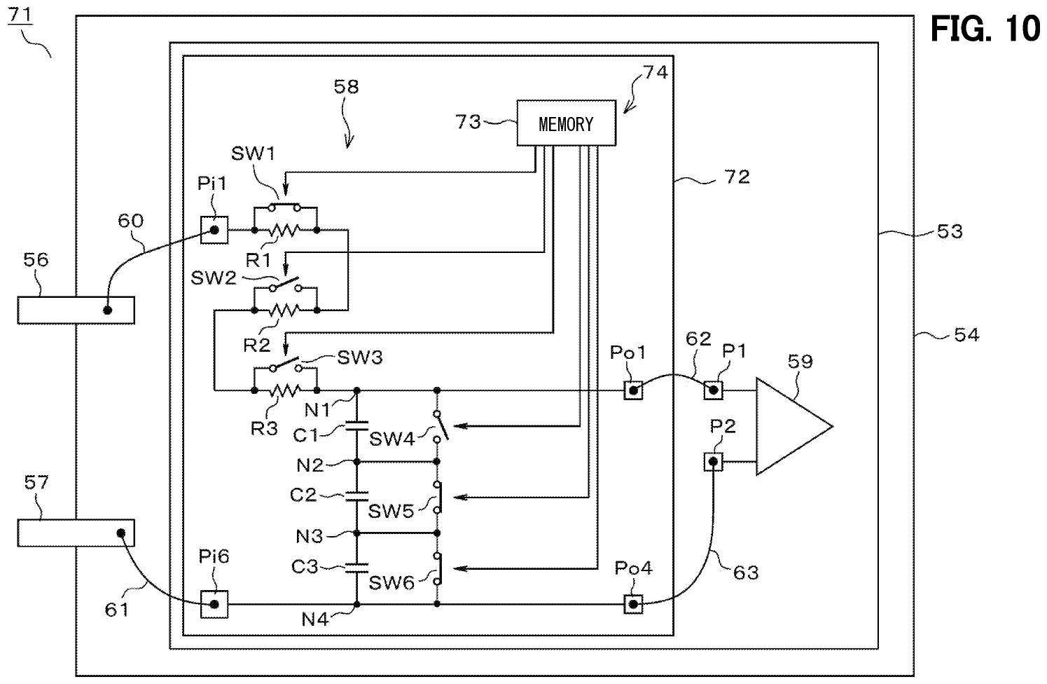

A fifth embodiment will be described below with reference to FIG. 10.

As illustrated in FIG. 10, a semiconductor device 71 of the present embodiment differs from the semiconductor device 51 of the fourth embodiment in that a filter chip 72 is provided instead of the filter chip 52 and in some other points. The filter chip 72 corresponding to the first semiconductor chip differs from the filter chip 52 in that the pads Pit to Pi5 and the pads Pot, Po3 are removed, in that switches SW1 to SW6 and a memory 73 are added, and in some other points.

In this case, the lead 56 is connected to the pad Pi1 of the filter chip 72 via the wire 60. In this case, the lead 57 is connected to the pad Pi6 of the filter chip 72 via the wire 61. In this case, the pad P2 of the monitoring IC chip 53 is connected to the pad Po4 of the filter chip 72 via the wire 63. The switches SW1 to SW6 are connected between terminals of at least some of the circuit elements each constituting the filter. Specifically, the switches SW1 to SW6 are connected as follows.

That is, the switches SW1, SW2, SW3 are connected between the terminals of the resistors R1, R2, R3, respectively. The switches SW4, SW5, SW6 are connected between the terminals of the capacitors C1, C2, C3, respectively. The on-off control of each of the switches SW1 to SW6 is performed based on a switching signal read from the memory 73. In the manufacturing stage of the semiconductor device 71, the memory 73 stores information different for each applied system, specifically, information corresponding to the switching signal described above, that is, information for switching on or off each of the switches SW1 to SW6.

The on-off control of each of the switches SW1 to SW3 is performed such that at least any one of the switches is turned off. The on-off control of each of the switches SW4 to SW6 is also performed such that at least any one of the switches is turned off. For example, when the semiconductor device 71 is for a predetermined system A, as illustrated in FIG. 10, the switches SW1, SW5, SW6 are turned on, and the switches SW2 to SW4 are turned off. When the semiconductor device 71 is for another system B different from the system A, all the switches SW1 to SW6 are turned off, although not illustrated.

In this case, the switches SW1 to SW6 and the memory 73 function as a function switching unit 74 that selectively switches the function of the filter 58, specifically, the constant of the filter 58. The function switching unit 74 switches on or off each of the switches SW1 to SW6 to switch the function of the filter 58. In this case, the function switching unit 74 switches on or off each of the switches SW1 to SW6 based on the information read from the memory 73.

With the above configuration, when the semiconductor device 71 is for the system A, each of the switches SW1 to SW6 is switched on or off as illustrated in FIG. 10, so that the resistance value of the filter 58 becomes the series combined resistance value of the resistors R2, R3, and the capacitance value of the filter 58 becomes the capacitance value of the capacitor C1. With the above configuration, when the semiconductor device 71 is for the system B, each of the switches SW1 to SW6 is switched on or off such that all the switches SW1 to SW6 are turned off, so that the resistance value of the filter 58 becomes the series combined resistance value of the resistors R1, R2, R3, and the capacitance value of the filter 58 becomes the series combined capacitance value of the capacitors C1, C2, C3.

With the configuration of the present embodiment described above, the constant of the filter 58 can be selectively switched as in the fourth embodiment. Hence, the present embodiment also provides the same effects as those of the fourth embodiment. Furthermore, with the configuration of the present embodiment, the constant of the filter 58 can be switched only by changing the data stored in the memory 73 in the manufacturing stage of the semiconductor device 71.

Therefore, according to the present embodiment, the semiconductor device 71 for a plurality of systems can be manufactured without changing the bonding wire process for each system. In the configuration of the present embodiment, the data of the memory 73 can be made rewritable even after the manufacturing of the semiconductor device 71. With such a configuration, even after the manufacturing of the semiconductor device 71, the constant of the filter 58 can be changed by switching on or off each of the switches SW1 to SW6.

### Sixth Embodiment

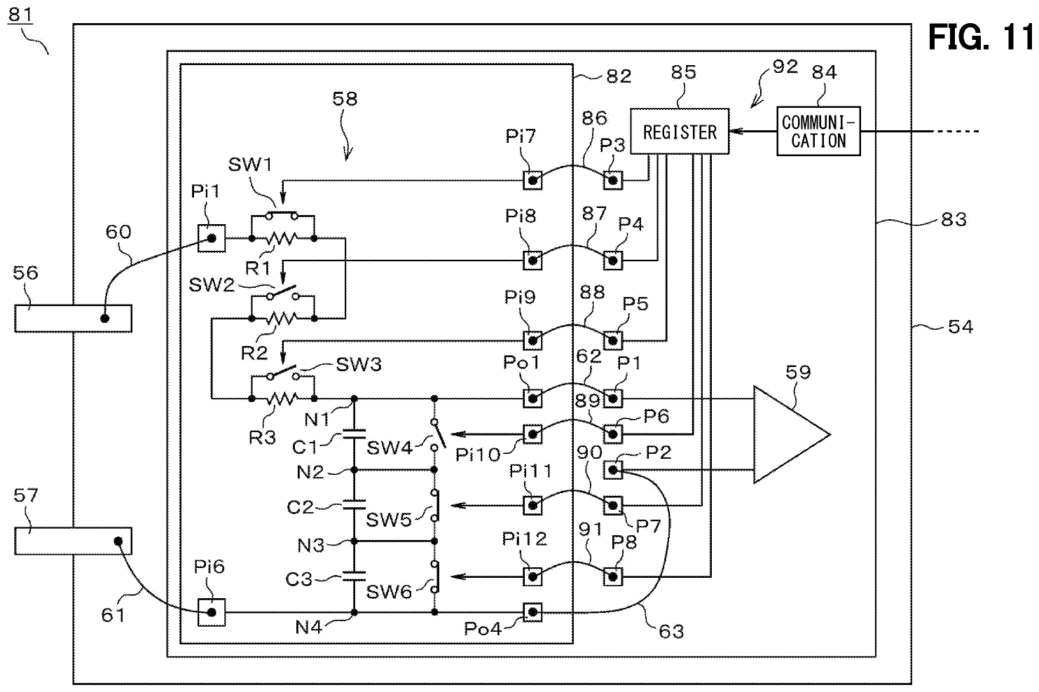

A sixth embodiment will be described below with reference to FIG. 11.

As illustrated in FIG. 11, a semiconductor device 81 of the present embodiment differs from the semiconductor device 71 of the fifth embodiment in that a filter chip 82 is provided in place of the filter chip 72, in that a monitoring IC chip 83 is provided in place of the monitoring IC chip 53, and in some other points. The filter chip 82 corresponding to the first semiconductor chip differs from the filter chip 72 in that the memory 73 is deleted, in that pads Pi7 to Pi12 are added, and in some other points.

The monitoring IC chip 83 corresponding to the second semiconductor chip differs from the monitoring IC chip 53 in that a communication unit 84, a register 85, and pads P3 to P8 are added and in some other points. The communication unit 84 is a communication interface for communicating with a device outside the semiconductor device 81. The register 85 stores information different for each system to be applied, specifically, information corresponding to a switching signal for switching on or off each of the switches SW1 to SW6. The information is stored into the register 85 based on a command given from a device outside the semiconductor device 81 via the communication unit 84.

The respective output terminals of the register 85 are connected to the terminals P3 to P8. The terminal P3 is connected to the pad Pi7 of the filter chip 82 via a wire 86. The terminal P4 is connected to the pad Pi8 of the filter chip 82 via a wire 87. The terminal P5 is connected to the pad Pi9 of the filter chip 82 via a wire 88. The terminal P6 is connected to the pad Pi10 of the filter chip 82 via a wire 89. The terminal P7 is connected to the pad Pi11 of the filter chip 82 via a wire 90. The terminal P8 is connected to the pad Pi11 of the filter chip 82 via a wire 91.

1In this case, the on-off control of each of the switches SW1 to SW6 is performed based on a switching signal read from the register 85 via each of the pads Pi7 to Pi12. In this case, the switches SW1 to SW6 and the register 85 function as a function switching unit 92 that selectively switches the function of the filter 58, specifically, the constant of the filter 58. The function switching unit 92 switches on or off each of the switches SW1 to SW6 to switch the function of the filter 58 in the same manner as the function switching unit 74. In this case, the function switching unit 92 switches on or off each of the switches SW1 to SW6 based on a command from the outside.

With the configuration of the present embodiment described above as well, the constant of the filter 58 can be selectively switched as in the fifth embodiment. Hence, the present embodiment also provides the same effects as those of the fifth embodiment. Furthermore, with the configuration of the present embodiment, the constant of the filter 58 can be switched only by changing the data stored in the register 85 in the manufacturing stage of the semiconductor device 81.

Therefore, according to the present embodiment, the semiconductor device 81 for a plurality of systems can be manufactured without changing the bonding wire process for each system. The data in the register 85 is rewritable even after the manufacturing of the semiconductor device 81. Therefore, according to the present embodiment, even after the manufacturing of the semiconductor device 81, the constant of the filter 58 can be changed by switching on or off each of the switches SW1 to SW6.

### Seventh Embodiment

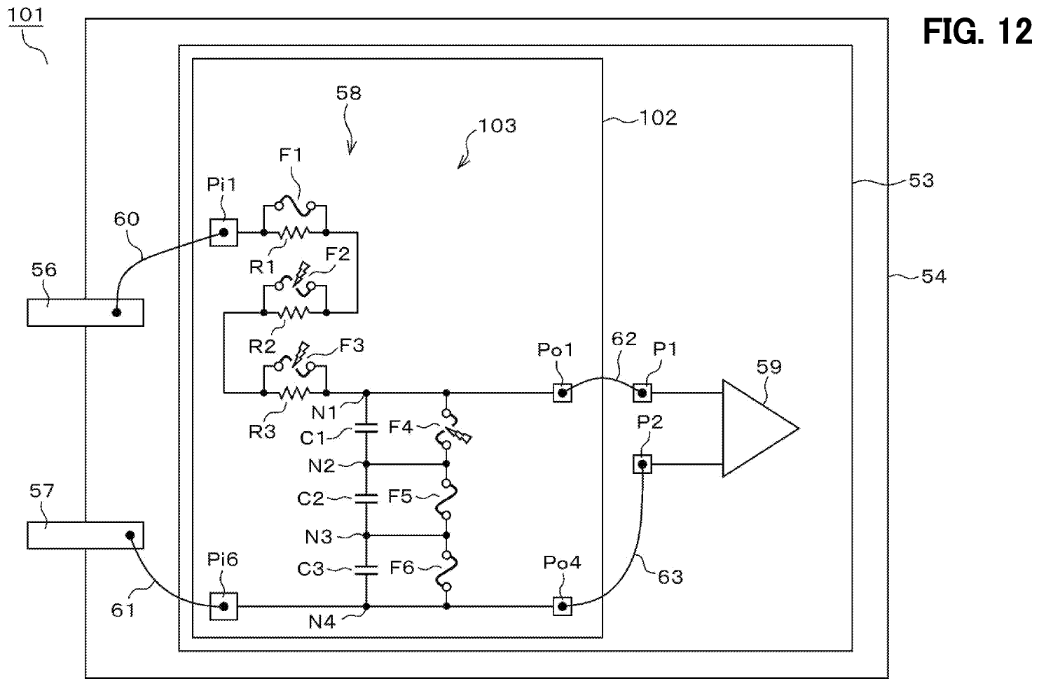

A seventh embodiment will be described below with reference to FIG. 12.

As illustrated in FIG. 12, a semiconductor device 101 of the present embodiment differs from the semiconductor device 71 of the fifth embodiment in that a filter chip 102 is provided instead of the filter chip 52 and in some other points. The filter chip 102 corresponding to the first semiconductor chip differs from the filter chip 72 in that fuses F1 to F6 are provided in place of the switches SW1 to SW6 and the memory 73 and in some other points.

The fuses F1 to F6 are connected between terminals of at least some of the circuit elements each constituting the filter. Specifically, the fuses F1 to F6 are connected as follows. That is, the fuses F1, F2, F3 are connected between the terminals of the resistors R1, R2, R3, respectively. The fuses F4, F5, F6 are connected between the terminals of the capacitors C1, C2, C3, respectively.

The fuses F1 to F6 can be cut off by laser cutting in a manufacturing stage or the like. Such laser cutting is performed such that the mode of whether or not the fuses F1 to F6 have been cut off is different for each applied system. In this case, at least one of the fuses F1 to F3 is cut off. In this case, at least one of the fuses F4 to F6 is cut off. For example, when the semiconductor device 101 is for a predetermined system A, the fuses F2, F3, F4 are cut off as illustrated in FIG. 12. When the semiconductor device 101 is for another system B different from the system A, all the fuses F1 to F6 are cut off, although not illustrated.

In this case, the fuses F1 to F6 function as a function switching unit 103 that selectively switches the function of the filter 58, specifically, the constant of the filter 58. The function switching unit 103 switches the function of the filter 58 depending on whether or not the fuses F1 to F6 have been cut off.

With the above configuration, when the semiconductor device 101 is for the system A, the fuses F2 to F4 are cut off as illustrated in FIG. 12, so that the resistance value of the filter 58 becomes the series combined resistance value of the resistors R2, R3, and the capacitance value of the filter 58 becomes the capacitance value of the capacitor C1. With the above configuration, when the semiconductor device 101 is for the system B, all the fuses F1 to F6 are cut off, so that the resistance value of the filter 58 becomes the series combined resistance value of the resistors R1, R2, R3, and the capacitance value of the filter 58 becomes the series combined capacitance value of the capacitors C1, C2, C3.

With the configuration of the present embodiment described above as well, the constant of the filter 58 can be selectively switched as in the fifth embodiment. Hence, the present embodiment also provides the same effects as those of the fifth embodiment. Furthermore, with the configuration of the present embodiment, the constant of the filter 58 can be switched only by changing which of the fuses F1 to F6 is to be cut off in the manufacturing stage of the semiconductor device 81. Therefore, according to the present embodiment, the semiconductor device 101 for a plurality of systems can be manufactured without changing the bonding wire process for each system.

### Eighth Embodiment

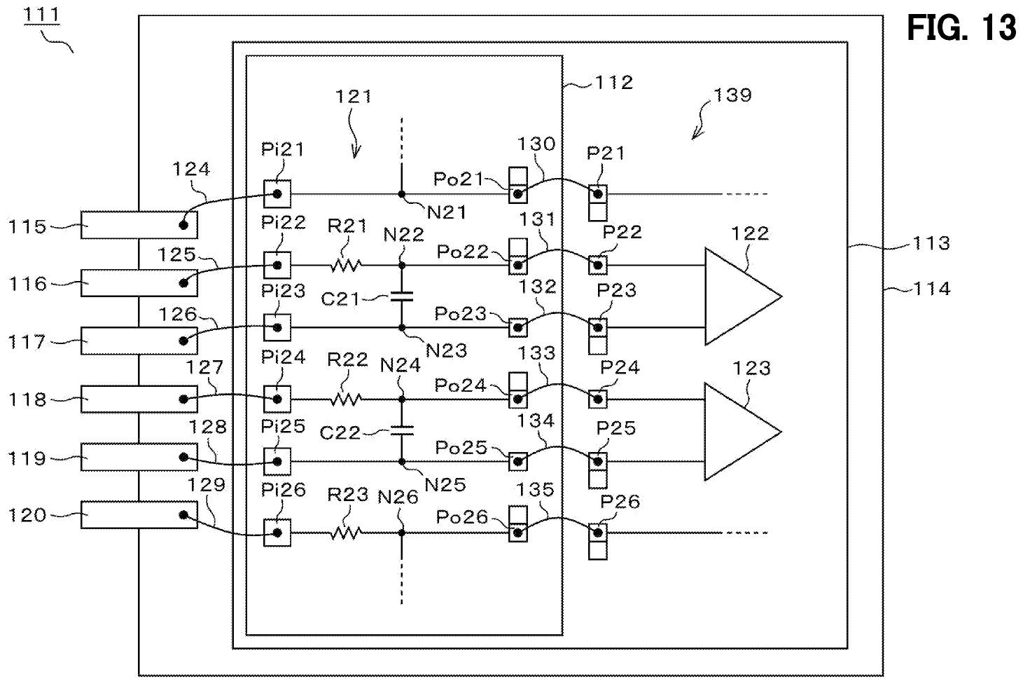

An eighth embodiment will be described below with reference to FIGS. 13 to 18.

As illustrated in FIGS. 13 to 15, a semiconductor device 111 of the present embodiment includes a filter chip 112 corresponding to the first semiconductor chip, a monitoring IC chip 113 corresponding to the second semiconductor chip, and a package 114 housing the filter chip 112 and the monitoring IC chip 113. Although FIGS. 13 to 15 mainly illustrate the respective configurations for detecting the voltages of two battery cells Cb, the configurations for detecting the voltages of the other battery cells Cb are the same. In the following description, one of the two battery cells Cb disposed on the high potential side is referred to as one battery cell Cb, and the other one disposed on the low potential side is referred to as the other battery cell Cb.

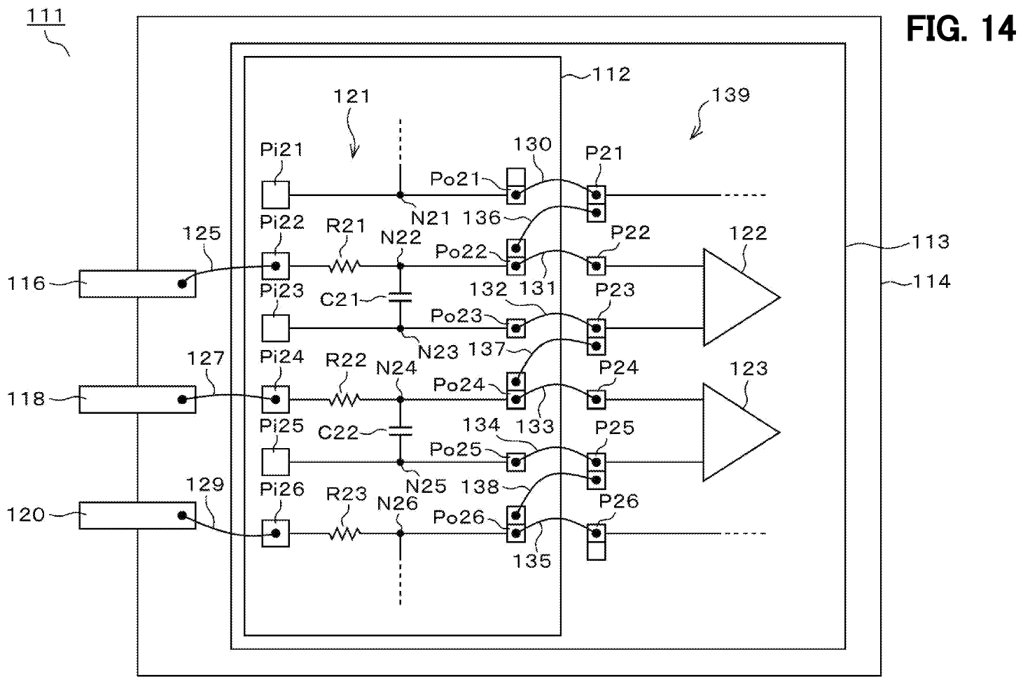

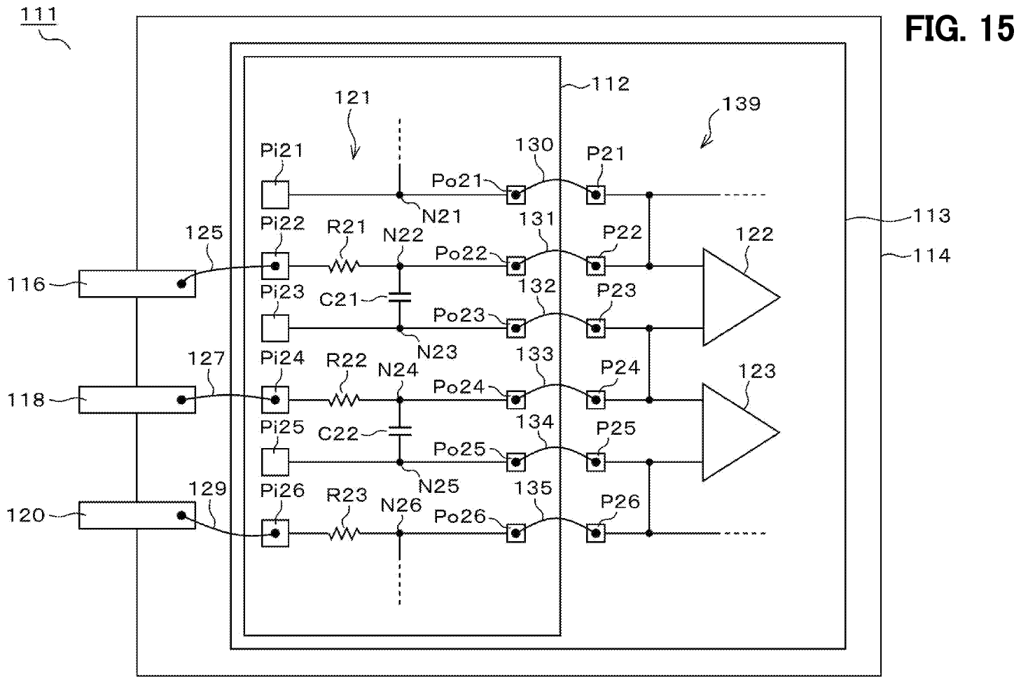

In the semiconductor device 111, the configuration of one or both of the monitoring IC chip 113 and the package 114 is changed in accordance with the system to which the semiconductor device 11 is applied, whereby three configurations are realized. Hereinafter, the three configurations will be referred to as a first configuration, a second configuration, and a third configuration, respectively. When the semiconductor device 111 has the first configuration, as illustrated in FIG. 13, the package 114 is provided with leads 115 to 120. When the semiconductor device 111 has the second configuration or the third configuration, as illustrated in FIG. 14 or 15, the package 114 is provided with leads 116, 118, 120.

When the semiconductor device 111 has the first configuration, the voltage of the low-potential-side terminal of the battery cell Cb adjacent to the high potential side of the one battery cell Cb is applied to the lead 115. In this case, the voltage of the high-potential-side terminal of the one battery cell Cb is applied to the lead 116, and the voltage of the low-potential-side terminal of the one battery cell Cb is applied to the lead 117. In this case, the voltage of the high-potential-side terminal of the other battery cell Cb is applied to the lead 118, and the voltage of the low-potential-side terminal of the other battery cell Cb is applied to the lead 119. In this case, the voltage of the high-potential-side terminal of the battery cell Cb adjacent to the low potential side of the other battery cell Cb is applied to the lead 120.

When the semiconductor device 111 has the second configuration or the third configuration, the voltage of the high-potential-side terminal of the one battery cell Cb is applied to the lead 116. In this case, the voltages of the low-potential-side terminal of the one battery cell Cb and the high-potential-side terminal of the other battery cell Cb, the terminals being connected in common, are applied to the lead 118. In this case, the voltages of the low-potential-side terminal of the other battery cell Cb and the high-potential-side terminal of the battery cell Cb adjacent to the low potential side of the other battery cell Cb, the terminals being connected in common, are applied to the lead 120.

In the filter chip 112, circuit elements constituting a filter 121 having the same role as the filter 13 in each of the above embodiments are formed. The filter 112 includes resistors R21 to R23 and capacitors C21, C22. The resistors R21 to R23 and the capacitors C21, C22 may have the same configurations as those of the resistors Rf and the capacitors Cf in each of the above embodiments.

Pads Pi21 to Pi26 and pads Po21 to Po26 are formed on the filter chip 112. The pad Pi21 is connected to the pad Po21. A node N21 existing in a path connecting the pad Pi21 and the pad Po21 is connected to another filter adjacent to the high potential side of the filter 121. The resistor R21 is connected between the pad Pi22 and a node N22. The node N22 is connected to the pad Po22. The capacitor C21 is connected between the node N22 and a node N23. The node N23 is connected to the pad Pi23 and the pad Po23.

The resistor R22 is connected between the pad Pi24 and a node N24. The node N24 is connected to the pad Po24. The capacitor C22 is connected between the node N24 and a node N25. The node N25 is connected to the pad Pi25 and the pad Po25. The resistor R23 is connected between the pad Pi26 and a node N26. The node N26 is connected to the pad Po26 and to another filter adjacent to the low potential side of the filter 121.

Battery monitoring units 122, 123 are formed on a monitoring IC chip 113. The battery monitoring units 122, 123 have the same configuration as that of the battery monitoring unit 59 in the fourth embodiment or the like. Pads P21 to P26 are formed on the monitoring IC chip 113. The pad P21 is connected to the other input terminal of the battery monitoring unit adjacent to the high potential side of the battery monitoring unit 122. The battery monitoring unit 122 has one input terminal connected to the pad P21 and the other input terminal connected to the pad P22.

The battery monitoring unit 123 has one input terminal connected to the pad P24 and the other input terminal connected to the pad P25. The pad P26 is connected to the one input terminal of the battery monitoring unit adjacent to the low potential side of the battery monitoring unit 123. When the semiconductor device 111 has the third configuration, as illustrated in FIG. 15, wiring for connecting the pad P21 and the pad P22, wiring for connecting the pad P23 and the pad P24, and wiring for connecting the pad P25 and the pad P26 are added.

When the semiconductor device 111 has the first configuration, as illustrated in FIG. 13, the lead 115 is connected to the pad Pi21 via a wire 124, the lead 116 is connected to the pad Pi22 via a wire 125, and the lead 117 is connected to the pad Pi23 via a wire 126. In this case, the lead 118 is connected to the pad Pi24 via a wire 127, the lead 119 is connected to the pad Pi25 via a wire 128, and the lead 120 is connected to the pad Pi26 via a wire 129.

When the semiconductor device 111 has the second configuration or the third configuration, as illustrated in FIG. 14 or 15, the lead 116 is connected to the pad Pi22 via the wire 125, the lead 118 is connected to the pad Pi24 via the wire 127, and the lead 120 is connected to the pad Pi26 via the wire 129.

When the semiconductor device 111 is the first configuration example or the third configuration example, as illustrated in FIG. 13 or 15, the pad P21 is connected to the pad Po21 via a wire 130, the pad P22 is connected to the pad Po22 via a wire 131, and the pad P23 is connected to the pad Po23 via a wire 132. In this case, the pad P24 is connected to the pad Po24 via a wire 133, the pad P25 is connected to the pad Po25 via a wire 134, and the pad P26 is connected to the pad Po26 via a wire 135.

When the semiconductor device 111 is the second configuration example, as illustrated in FIG. 14, the pads P21 to P26 are connected to the pads Po21 to Po26 via the wires 130 to 135, respectively, in the same manner as in the first or third configuration example. Further, in this case, the pad P21 is connected to the pad Po22 via a wire 136, the pad P23 is connected to the pad Po24 via a wire 137, and the pad P25 is connected to the pad Po26 via a wire 138

The wires 124 to 138 are bonding wires, and the same structure as that of the wire 11 or the like in each of the above embodiments can be adopted. In this case, the wiring of the wires 124 to 138 and the monitoring IC chip 113 functions as a function switching unit 139 for selectively switching the function of the filter 121, specifically, the circuit configuration of the filter 121. In this case, the function switching unit 139 switches the connection mode of each of the wires 124 to 138 connected to the filter chip 112 and the wiring of the monitoring IC chip 113 to switch the filter 121 between a single-type RC filter and a non-single-type RC filter.

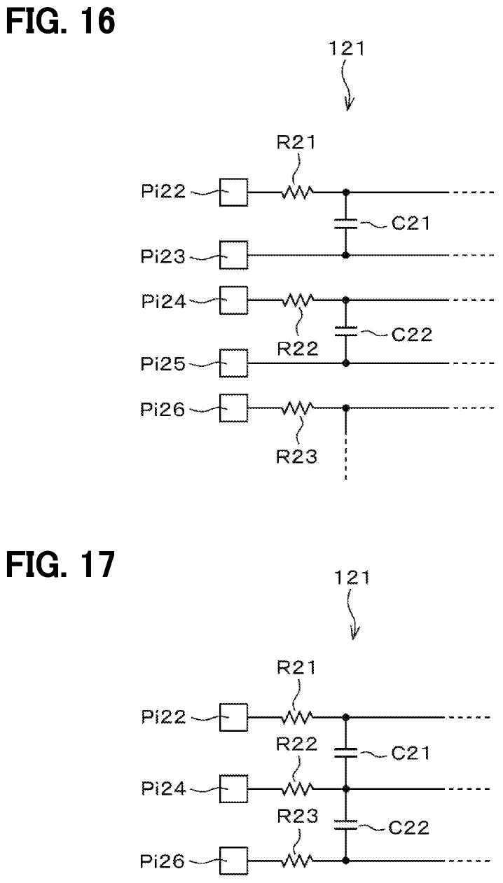

When the semiconductor device 111 is the first configuration example, as illustrated in FIG. 13, the leads 115 to 120 and the filter chip 112 are connected via the wires 124 to 129, and the monitoring IC chip 113 and the filter chip 112 are connected via the wires 130 to 135. Thus, the filter 121 has a circuit configuration as illustrated in FIG. 16, that is, a circuit configuration of a single L-type RC filter.

When the semiconductor device 111 is the second configuration example, as illustrated in FIG. 14, the leads 116, 118, 120 and the filter chip 112 are connected via the wires 125, 127, 129, and the monitoring IC chip 113 and the filter chip 112 are connected via the wires 130 to 138. Thus, the filter 121 has a circuit configuration as illustrated in FIG. 17, that is, a circuit configuration of a non-single n-type RC filter.

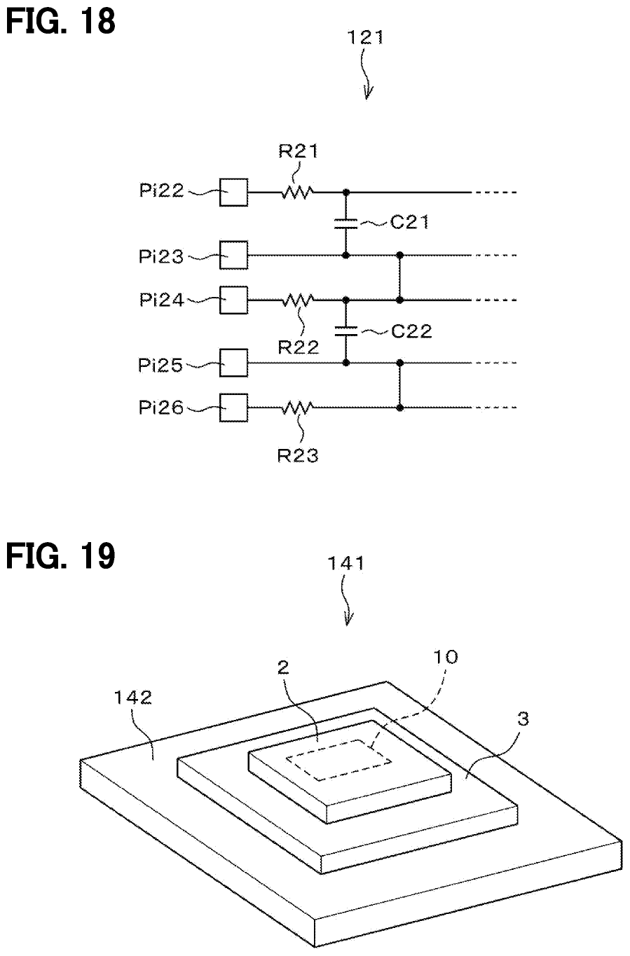

When the semiconductor device 111 is the third configuration example, as illustrated in FIG. 15, the leads 116, 118, 120 and the filter chip 112 are connected via the wires 125, 127, 129, and the monitoring IC chip 113 and the filter chip 112 are connected via the wires 130 to 135. In this case, in the monitoring IC chip 113, wiring for connecting the pad P21 and the pad P22, wiring for connecting the pad P23 and the pad P24, and wiring for connecting the pad P25 and the pad P26 are added. Thus, the filter 121 has a circuit configuration as illustrated in FIG. 18, that is, a circuit configuration of a non-single n-type RC filter.

With the configuration of the present embodiment described above, the function of the filter 121, specifically, the circuit configuration of the filter 121, can be switched selectively. Therefore, according to the present embodiment, the circuit configuration of the filter 121 can be optimized in accordance with the system of the vehicle to which the battery monitoring system is applied, that is, the optimum filter 121 can be realized. In addition, with the configuration of the present embodiment, since the circuit configuration of the filter 121 can be easily changed, it is possible to cope with a system in a wide noise environment.

Furthermore, with the configuration of the present embodiment, the circuit configuration of the filter 121 can be switched by changing the configuration of the monitoring IC chip 113, changing the configuration of the package 114, or switching the connection mode of the bonding wire, or by some other means without changing the configuration of the filter chip 112. Therefore, according to the present embodiment, the semiconductor device 111 for a plurality of systems can be manufactured using one type of filter chip 112, and the manufacturing cost can be reduced because the filter chip 112 can be shared.

### Ninth Embodiment

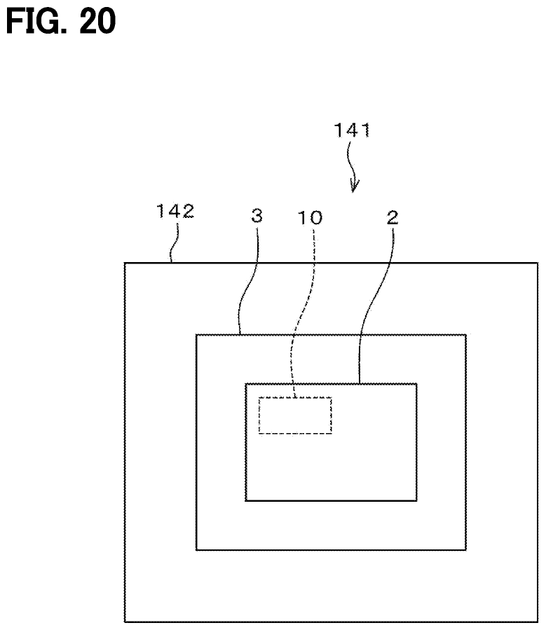

A ninth embodiment will be described below with reference to FIGS. 19 and 20.

As illustrated in FIGS. 19 and 20, in a semiconductor device 141 of the present embodiment, a high-voltage power supply chip 142 is added to the semiconductor device 1 of the first embodiment as a semiconductor chip housed in the package 4. The high-voltage power supply chip 142 is a plate-like semiconductor chip made of a semiconductor such as silicon. In the high-voltage power supply chip 142, a power supply circuit that reduces the voltage of the battery cell Cb, which becomes a relatively high voltage, to generate a power supply voltage for the monitoring IC chip 3 is formed.

The plane size of the high-voltage power supply chip 142 is larger than the plane sizes of the filter chip 2 and the monitoring IC chip 3. In this case, the high-voltage power supply chip 142, the monitoring IC chip 3, and the filter chip 2 are laminated in this order, and these chips are sealed with a mold resin. With such a configuration, the entire reference power supply circuit 10 formed in the monitoring IC chip 3 is not only located on the inner periphery of the outer contour of the filter chip 2 but also located on the inner periphery of the outer contour of the high-voltage power supply chip 142. That is, in the above configuration, the entire reference power supply circuit 10 is covered with the filter chip 2 and the high-voltage power supply chip 142.

The semiconductor device 141 according to the present embodiment described above has a stack structure in which the chips are laminated such that the monitoring IC chip 3 is sandwiched between the filter chip 2 and the high-voltage power supply chip 142. The entire reference power supply circuit 10 formed in the monitoring IC chip 3 is covered with the filter chip 2 and the high-voltage power supply chip 142. With such a configuration, the effect of alleviating the influence of stress caused by the expansion and contraction of a package described in the first embodiment can be further enhanced, and as a result, the fluctuation of the reference voltage Vref generated by the reference power supply circuit 10 can be further reduced.

With the configuration of the present embodiment, the high-voltage power supply chip 142, which has been conventionally configured as a different IC, is incorporated into the same package as the filter chip 2 and the monitoring IC chip 3 to form one semiconductor device 141, so that the circuit board on which the respective components of the battery monitoring function, including the semiconductor device 142, are to be mounted can be further reduced in size. According to the present embodiment, the circuit board is reduced in size in this manner, whereby the wiring impedance and the inductor of the ground are reduced, and as a result, it is possible to obtain an effect that the influence of power supply noise and the like caused by the operation of the power supply circuit is reduced for the voltage detection of the battery cell Cb, which is the main function in the battery monitoring.

### Tenth Embodiment

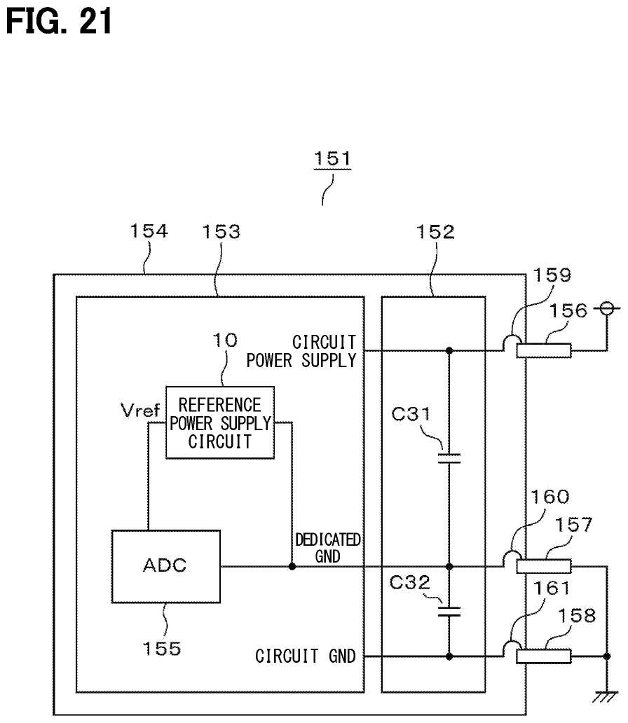

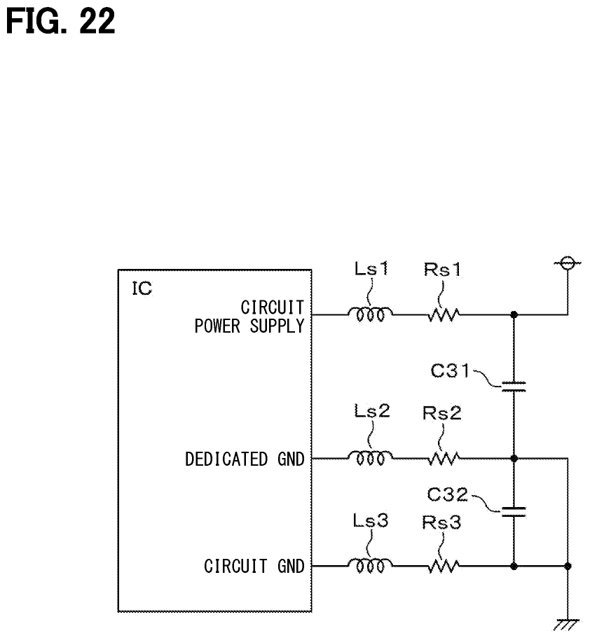

A tenth embodiment will be described below with reference to FIGS. 21 and 22.

As illustrated in FIG. 21, a semiconductor device 151 of the present embodiment differs from the semiconductor device 1 of the first embodiment in that a filter chip 152 is provided in place of the filter chip 2, in that a monitoring IC chip 153 is provided in place of the monitoring IC chip 3, in that a package 154 is provided in place of the package 4, and in some other points.

The filter chip 152 corresponds to the first semiconductor chip and is provided with capacitors C31, C32 in addition to the same configuration as the filter chip 2. The capacitors C31, C32 have been conventionally used as external components of the IC and are stabilization capacitors for stabilizing the circuit power supply of the monitoring IC chip 153, that is, bypass capacitors. The monitoring IC chip 153 corresponds to the second semiconductor chip and includes, in addition to the reference power supply circuit 10 provided in the monitoring IC chip 3, an analog-to-digital (A/D) converter 155 to which the reference voltage Vref generated by the reference power supply circuit 10 is supplied. In the present specification, the A/D converter may be abbreviated as an ADC.

The capacitor C31 is connected between the circuit power supply of the monitoring IC chip 3 and a dedicated GND serving as a ground potential in the reference power supply circuit 10 and the ADC 155. The capacitor C32 is connected between the dedicated GND and a circuit GND serving as a ground potential in each circuit of the monitoring IC chip 153.

The package 154 houses the filter chip 152 and the monitoring IC chip 153 and includes leads 156 to 158. A power supply voltage corresponding to the circuit power supply is supplied to the lead 156 from the outside of the semiconductor device 151. A ground potential is supplied to the leads 157, 158 from the outside of the semiconductor device 151. The lead 156 is connected to one terminal of the capacitor C31 via a wire 159. The lead 157 is connected to the other terminal of the capacitor C31 and one terminal of the capacitor C32 via a wire 160. The lead 158 is connected to the other terminal of the capacitor C32 via a wire 161.

In the semiconductor device 151 of the present embodiment described above, the capacitors C31, C32, which have been conventionally external components of an IC, are incorporated and integrated into the semiconductor device 151. With such a configuration, the following effects can be obtained. That is, as in a comparative example illustrated in FIG. 22, when the capacitors C31, C32 are externally attached to the IC, the effect of noise removal by the capacitors C31, C32 is reduced due to the influence of parasitic inductances Ls1, Ls2 Ls3 and parasitic resistors Rs1, Rs2, Rs3 caused by wires, wiring, and the like between the capacitors C31, C32 and the circuit inside the IC.

In contrast, according to the semiconductor device 151 of the present embodiment, parasitic inductances and resistances between the capacitors C31, C32 and the circuit can be made very small. For this reason, according to the present embodiment, the effect of noise removal by the capacitors C31, C32 is enhanced sufficiently. Therefore, according to the present embodiment, the circuit characteristics of the reference power supply circuit 10, the ADC 155, and the like can be improved, and as a result, the voltage detection accuracy of the battery cell Cb can be improved. In a case where the semiconductor device 151 is provided with a semiconductor chip different from the filter chip 152 and the monitoring IC chip 153, the capacitors C31, C32 may be provided on the different semiconductor chip. With such a configuration as well, the effects described above can be obtained.

### Other Embodiments

Note that the present disclosure is not limited to each of the embodiments described above in the drawings but can be arbitrarily modified, combined, or expanded without departing from the scope of the disclosure.

The numerical values and the like shown in each of the above embodiments are merely examples, and the present disclosure is not limited thereto.

The resistor Rf may be formed of another type of resistor such as a thin-film resistor. That is, when the resistor Rf is formed in each of the filter chips 2, 32, 33, the type of the resistor Rf may be appropriately determined by the process of forming the capacitor Cf on each of the filter chips 2, 32, 33. The thin-film resistor is formed in the wiring layer and can thus be disposed even directly above the capacitor Cf, especially directly above the dielectric 19. Thus, when the resistor Rf is formed of the thin-film resistor, the area efficiency is improved compared to a case where the resistor Rf is formed of the poly resistor. On the other hand, the process cost of the poly resistor can be kept lower than that of the thin-film resistor. Thus, when the resistor Rf is formed of the poly resistor, the manufacturing cost can be kept lower than the case where the resistor Rf is formed of the thin-film resistor.

Each of the filter chips 2, 32, 33 only needs to include at least some of the capacitors Cf constituting the filters 13. Therefore, some of the capacitors Cf constituting the filters 13, the resistors Rf constituting the filters 13, and the like may be provided outside the semiconductor device 1 as external components. When the resistor Rf is provided as an external component, the effect of reducing the size of the circuit board decreases compared to a case where the resistor Rf is integrated, but it is possible to obtain the effect of being flexible in the matching of the constants of the filters 13, that is, facilitating the matching of the constants.

In each of the filter chips 2, 32, 33, an element that is a circuit different from the filter 13 and constitutes a circuit related to the input of a physical quantity to the monitoring IC chip 3, such as a discharge resistor Rn or a protection diode may be formed, or another circuit element such as a bypass capacitor, a damping resistor, a pull-up resistor, or a pull-down resistor may be formed. Furthermore, as the first semiconductor chip, a chip may have at least another circuit element described above formed therein. With any of these configurations, the circuit board can be reduced in size by integrating a circuit element, which has been conventionally an external component of an IC.

In each of the filter chips 2, 32, 33, the arrangement order of the capacitors Cf constituting the filters 13 in the lateral direction and the longitudinal direction, that is, the plane layout, is not limited to that described in each of the above embodiments but may be changed as appropriate.

The potential on the back surface of each of the filter chips 2, 32, 33 is not limited to the ground potential in the monitoring IC chip 3 but may be a predetermined fixed potential in the monitoring IC chip 3 or may be floating. When the potential on the back surface side is set to be floating, the withstand voltage requirement can be relaxed compared to a case where the potential on the back surface side is set to be a ground potential. For example, focusing on the region where the capacitor Cf3 is formed in FIG. 4, when the potential on the back surface side is ideal floating, the withstand voltage requirement by the isolation layer 23 located below the region where the capacitor Cf3 is formed is half of that in a case where the potential on the back surface side is a ground potential.

In each of the above embodiments, since the plane size P1 of the filter chip 2 is smaller than the plane size P2 of the monitoring IC chip 3, the configuration in which the filter chip 2 is laminated on the monitoring IC chip 3 has been adopted. However, the vertical relationship between the filter chip 2 and the monitoring IC chip 3 may be reversed. For example, when the plane size P1 of the filter chip 2 is larger than the plane size P2 of the monitor IC chip 3 due to the relatively large capacitance of the capacitor Cf constituting the filter 13, it is desirable to adopt a configuration in which the monitoring IC chip 3 is laminated on the filter chip 2 in consideration of balance and the like.

In the second embodiment, the plurality of filter chips 32, 33 have been disposed side by side on a plane, but when the filter chips are divided into a plurality of pieces, the plurality of filter chips may be disposed by being laminated vertically. That is, the semiconductor chips including the monitoring IC chip 3 may be laminated in three or more stages. However, there is a restriction due to wire bonding, and hence the number of stages to be laminated is limited to the number of stages within the restriction.

In each of the filter chips 2, 32, 33, the isolation layer 23, which is the element isolating structure, may be provided only between a region where the predetermined capacitor Cf is formed and a region adjacent thereto where another capacitor Cf is formed. In other words, the isolation layer 23 does not need to be provided between the region where the predetermined capacitor Cf is formed and the region on the back surface side of each of the filter chips 2, 32, 33. Even in such a configuration, for example, when a material having relatively high insulation performance is used as the joint material 9, which is the DAF, the problem of the back surface potential of each of the filter chips 2, 32, 33 and the potentials of the monitoring IC chip 3 and the island 5 does not occur.

The function switching unit 139 of the eighth embodiment has switched the connection mode of the wires 124 to 138 connected to the filter chip 112 to switch the circuit configuration of the filter 121, but the switching method can be modified as follows. That is, as in the fifth or sixth embodiment, a switch connected between the terminals of at least some of the circuit elements each constituting the filter 121 may be provided, and the function switching unit 139 may switch on or off the switch to switch the circuit configuration of the filter 121.

In this case, as in the fifth embodiment, the function switching unit 139 may switch on or off the switch based on the information read from the memory storing the information for switching on or off the switch or may switch on or off the switch based on a command from the outside. Alternatively, as in the seventh embodiment, fuses connected between the terminals of at least some of the circuit elements each constituting the filter 121 may be provided, and the function switching unit 139 may switch the circuit configuration of the filter 121 based on whether or not the fuses have been cut off.

Although the present disclosure has been described in accordance with embodiments, it is understood that the present disclosure is not limited to such embodiments or structures. The present disclosure encompasses various modifications and variations within an equivalent scope. In addition, various combinations and forms, as well as other combinations and forms including only one element, more than that, or less than that, are also within the scope and idea of the present disclosure.

What is claimed is:

1. A semiconductor device comprising:
at least one first semiconductor chip in which a plurality of capacitors are provided by integrating trench capacitors to form a filter that receives, as an input, a physical quantity relating to a plurality of battery cells for forming an assembled battery;
a second semiconductor chip in which a circuit is provided, the circuit executing a predetermined process for monitoring the assembled battery based on an output of the filter; and
one package that accommodates the first semiconductor chip and the second semiconductor chip, wherein:
the first semiconductor chip has a structure for an element isolation between a region where a predetermined numerical number of capacitors among the plurality of capacitors are arranged and another region.

2. The semiconductor device according to claim 1, wherein:
the structure for the element isolation is arranged between the region where the predetermined numerical number of capacitors are arranged and the other region where another capacitor adjacent to the region is arranged.

3. The semiconductor device according to claim 1, wherein:
the structure for the element isolation is arranged between the region where the predetermined numerical number of capacitors are formed and the other region on a back surface side of the first semiconductor chip.

4. The semiconductor device according to claim 1, wherein:
a potential on a back surface side of the first semiconductor chip corresponds to a predetermined fixed potential in the second semiconductor chip.

5. The semiconductor device according to claim 1, wherein:
a potential on a back surface side of the first semiconductor chip is floating.

6. The semiconductor device according to claim 1, wherein:
the first semiconductor chip includes a resistor for providing the filter.

7. The semiconductor device according to claim 1, wherein:
the first semiconductor chip includes an element that provides a circuit different from the filter, and relates to the input of the physical quantity with respect to the second semiconductor chip.

8. The semiconductor device according to claim 1, wherein:
the at least one first semiconductor chip includes a plurality of first semiconductor chips.

9. The semiconductor device according to claim 1, wherein:
the first semiconductor chip is stacked on the second semiconductor chip.

10. The semiconductor device according to claim 9, wherein:
a plane size of the first semiconductor chip is larger than a plane size of an important circuit that has a relatively high degree of importance in terms of a function among circuits disposed in the second semiconductor chip; and
a whole of the important circuit is covered with the first semiconductor chip, and the whole of the important circuit is located inside of an outer periphery of the first semiconductor chip.

11. The semiconductor device according to claim 1, wherein:
the plurality of capacitors are arranged in a matrix in which a part of the plurality of capacitors are arranged in a first direction of a plane direction of the first semiconductor chip, and another part of the plurality of capacitors are arranged in a second direction orthogonal to the first direction; and
an arrangement order of the capacitors in the first direction is set to match a difference between respective common voltages of two of the capacitors adjacent to each other in the first direction to be a voltage corresponding to a cell voltage that is a voltage of each of the battery cells.

12. The semiconductor device according to claim 11, wherein:
an arrangement order of the capacitors in the second direction is set to match a difference between respective common voltages of two of the capacitors adjacent to each other in the second direction to be a voltage obtained by multiplying the cell voltage by a numerical number of the capacitors arranged in the first direction.

13. The semiconductor device according to claim 1, wherein:
a region having a predetermined fixed potential is disposed between adjacent capacitors.

14. The semiconductor device according to claim 1, further comprising:
a function switching unit that selectively switches a function of the filter.

15. The semiconductor device according to claim 14, wherein:
the function switching unit electively switches a filter constant of the filter.

16. The semiconductor device according to claim 14, wherein:
the function switching unit selectively switches a circuit configuration of the filter.

17. The semiconductor device according to claim 14, wherein:
the function switching unit switches a connection mode of a bonding wire connected to the first semiconductor chip to switch the function of the filter.

18. The semiconductor device according to claim 14, wherein:
the first semiconductor chip includes a switch connected between terminals of at least a part of the plurality of circuit elements for providing the filter; and
the function switching unit switches on or off the switch to switch the function of the filter.

19. The semiconductor device according to claim 18, wherein:
the function switching unit includes a memory that stores information for switching on or off the switch; and
the function switching unit switches on or off the switch based on the information stored in the memory.

20. The semiconductor device according to claim 18, wherein:
the function switching unit switches on or off the switch based on a command from an external device.

21. The semiconductor device according to claim 14, wherein:
the first semiconductor chip includes a fuse connected between terminals of at least a part of the plurality of circuit elements for providing the filter; and
the function switching unit switches the function of the filter based on whether the fuse is cut off.
